(19) United States
(12) Patent Application Publication
(10) Pub. No.: US 2025/0350258 A1
(43) Pub. Date: Nov. 13, 2025

(54) ACOUSTIC WAVE DEVICE

(71) Applicant: Murata Manufacturing Co., Ltd., Nagaokakyo-shi (JP)

(72) Inventors: Takuro OKADA, Nagaokakyo-shi (JP); Kentaro NAKAMURA, Nagaokakyo-shi (JP); Takuya YABU, Nagaokakyo-shi (JP)

(21) Appl. No.: 19/278,447

(22) Filed: Jul. 23, 2025

Related U.S. Application Data
(63) Continuation of application No. PCT/JP2023/041837, filed on Nov. 21, 2023.

(30) Foreign Application Priority Data
Jan. 25, 2023 (JP) 2023-009571

(51) Int. Cl. H03H 9/145; H03H 9/02; H03H 9/64

(52) U.S. Cl. CPC H03H 9/14561; H03H 9/14541; H03H 9/02818; H03H 9/6483

(57) ABSTRACT

An acoustic wave device includes a piezoelectric substrate including a piezoelectric layer, and resonator electrodes on the piezoelectric substrate and each including electrode fingers and an IDT electrode. The resonator electrodes include first and second resonator electrodes. At least one of the first and second resonator electrodes includes a curved resonator electrode in which the electrode fingers have a curved shape in plan view. The first and second resonator electrodes face each other, and a resonator electrode is positioned on a convex side, in a direction in which the electrode fingers are arranged, of a portion including the curved shape of the curved resonator electrode.

### CROSS REFERENCE TO RELATED APPLICATIONS

This application claims the benefit of priority to Japanese Patent Application No. 2023-009571 filed on Jan. 25, 2023 and is a Continuation application of PCT Application No. PCT/JP2023/041837 filed on Nov. 21, 2023. The entire contents of each application are hereby incorporated herein by reference.

### BACKGROUND OF THE INVENTION

### 1. Field of the Invention

The present invention relates to acoustic wave devices each including a plurality of acoustic wave resonators.

### 2. Description of the Related Art

Acoustic wave devices have been widely used in filters of mobile phones and other devices. Chinese Patent Application Publication No. 113676149 discloses an example of acoustic wave devices. This acoustic wave device includes an interdigital transducer (IDT) electrode on a piezoelectric substrate. Each of the plurality of electrode fingers of the IDT electrode has the shape of a circular arc. More specifically, the plurality of electrode fingers have shapes corresponding to circular arcs of respective concentric circles. In the acoustic wave device of Chinese Patent Application Publication No. 113676149 specification, spurious waves are suppressed.

The inventors of example embodiments of the present invention have discovered that when the plurality of electrode fingers have curved shapes, acoustic waves tend to leak toward the inside of the curved shapes. Therefore, in the case where another resonator is provided near an acoustic wave resonator including a curved IDT electrode, the modes of the resonators may interfere with each other and may be acoustically coupled. This may result in degradation of the electrical characteristics, such as an increase in insertion loss and the generation of spurious waves.

### SUMMARY OF THE INVENTION

Example embodiments of the present invention provide acoustic wave devices each able to reduce or prevent acoustic coupling between acoustic wave resonators and to thus reduce or prevent the degradation of the electrical characteristics.

An acoustic wave device according to an example embodiment of the present invention piezoelectric substrate including a piezoelectric layer, and a plurality of resonator electrodes on the piezoelectric substrate and each including a plurality of electrode fingers. Each of the plurality of resonator electrodes includes an interdigital transducer (IDT) electrode, the plurality of resonator electrodes include a first resonator electrode and a second resonator electrode, at least one of the first resonator electrode and the second resonator electrode is a curved resonator electrode in which each of the plurality of electrode fingers has a curved shape in plan view, and the first resonator electrode and the second resonator electrode face each other, and of the first resonator electrode and the second resonator electrode, another resonator electrode is positioned on a convex side, in the direction in which the plurality of electrode fingers are arranged, of a portion including the curved shape of the electrode finger in the resonator electrode that is the curved resonator electrode.

An acoustic wave device according to another example embodiment of the present invention includes a piezoelectric substrate including a piezoelectric layer, and a plurality of resonator electrodes on the piezoelectric substrate and each including a plurality of electrode fingers. The piezoelectric layer includes a propagation axis, each of the plurality of resonator electrodes includes an interdigital transducer (IDT) electrode, the plurality of electrode fingers of the IDT electrode include a plurality of first electrode fingers and a plurality of second electrode fingers interdigitated with each other, a distance between a first envelope and a second envelope is referred to as an intersecting width where the first envelope is a virtual line connecting tips of the plurality of second electrode fingers and the second envelope is a virtual line connecting tips of the plurality of first electrode fingers, the plurality of resonator electrodes include a first resonator electrode and a second resonator electrode, of the first resonator electrode and the second resonator electrode, at least the first resonator electrode is a curved resonator electrode in which each of the plurality of electrode fingers has a curved shape in plan view, the first resonator electrode and the second resonator electrode face each other, the second resonator electrode is positioned on a concave side in the direction in which the plurality of electrode fingers are arranged, of a portion including the curved shape of the electrode finger in the first resonator electrode, where the propagation axis extends in a first direction, a first distance denotes a shortest distance in the first direction between the first resonator electrode and the second resonator electrode, where a second direction is a direction perpendicular or substantially perpendicular to the first direction, a second distance denotes a distance in the second direction between a center portion in the second direction of the electrode finger of the first resonator electrode that is positioned closest to the second resonator electrode and a center portion in the second direction of the electrode finger of the second resonator electrode that is positioned closest to the first resonator electrode, a proximal intersecting width denotes a shorter one of the intersecting width at a portion of the IDT electrode of the first resonator electrode that is positioned closest to the second resonator electrode and the intersecting width at a portion of the IDT electrode of the second resonator electrode that is positioned closest to the first resonator electrode, and the acoustic wave device includes at least one of a configuration in which the first distance is at least about 32λ where λ is a wavelength determined by an electrode finger pitch of the first resonator electrode, and a configuration in which (Ly/La)×100 [%]≥about 12.4 [%] where Ly is the second distance and La is the proximal intersecting width.

An acoustic wave device according to another example embodiment of the present invention includes a piezoelectric substrate including a piezoelectric layer, and a plurality of resonator electrodes on the piezoelectric substrate and each including a plurality of electrode fingers. The piezoelectric layer includes a propagation axis, each of the plurality of resonator electrodes includes an interdigital transducer (IDT) electrode and a pair of reflectors facing each other across the IDT electrode, the IDT electrode and the pair of reflectors each include the plurality of electrode fingers, the plurality of resonator electrodes include a first resonator electrode and a second resonator electrode, of the first resonator electrode and the second resonator electrode, at least the first resonator electrode is a curved resonator electrode in which each of the plurality of electrode fingers has a curved shape in plan view, a first proximal electrode finger denotes one of the plurality of electrode fingers of the first resonator electrode that is positioned closest to the second resonator electrode, a second proximal electrode finger denotes one of the plurality of electrode fingers of the second resonator electrode that is positioned closest to the first resonator electrode, of the pair of reflectors of the first resonator electrode, a number of the plurality of electrode fingers of the reflector positioned closer to the IDT electrode of the second resonator electrode is greater than a number of the plurality of electrode fingers of the other reflector.

An acoustic wave device according to another example embodiment of the present invention includes a piezoelectric substrate including a piezoelectric layer, and a plurality of resonator electrodes on the piezoelectric substrate and each including a plurality of electrode fingers. Each of the plurality of resonator electrodes includes an interdigital transducer (IDT) electrode, the plurality of resonator electrodes include a first resonator electrode and a second resonator electrode, and of the first resonator electrode and the second resonator electrode, at least the first resonator electrode is a curved resonator electrode in which each of the plurality of electrode fingers has a curved shape in plan view, the acoustic wave device further includes an acoustic scattering pattern between the first resonator electrode and the second resonator electrode on the piezoelectric substrate.

An acoustic wave device according to another example embodiment of the present invention includes a piezoelectric substrate including a piezoelectric layer, and a plurality of resonator electrodes on the piezoelectric substrate and each including a plurality of electrode fingers. The piezoelectric layer includes a propagation axis, each of the plurality of resonator electrodes includes an interdigital transducer (IDT) electrode, the plurality of electrode fingers of the IDT electrode include a plurality of first electrode fingers and a plurality of second electrode fingers interdigitated with each other, an intersecting region denotes a region between a first envelope and a second envelope where the first envelope is a virtual line connecting tips of the plurality of second electrode fingers and the second envelope is a virtual line connecting tips of the plurality of first electrode fingers, the plurality of resonator electrodes include a first resonator electrode and a second resonator electrode, of the first resonator electrode and the second resonator electrode, at least the first resonator electrode is a curved resonator electrode in which each of the plurality of electrode fingers has a curved shape in plan view, the first resonator electrode and the second resonator electrode are adjacent to each other, and where the propagation axis extends in a first direction, the intersecting region of the first resonator electrode does not overlap the intersecting region of the second resonator electrode when viewed in the first direction.

According to example embodiments of the present invention, it is possible to reduce or prevent acoustic coupling between acoustic wave resonators and thus reduce or prevent degradation of electrical characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic sectional view along a line I-I in FIG. 1.

FIG. 3 is a schematic plan view for explaining the configuration of a first IDT electrode in the first example embodiment of the present invention.

FIG. 4 is a simplified plan view illustrating an example of the wiring configuration of the acoustic wave device according to the first example embodiment of the present invention.

FIG. 5 is a schematic plan view of the acoustic wave device for explaining a first distance Lx and a second distance Ly.

FIG. 6 is a simplified plan view illustrating the wiring configuration of an acoustic wave device of a comparative example.

FIG. 7 is a diagram illustrating the return loss in the comparative example.

FIG. 8 is a diagram illustrating the return loss in the first example embodiment of the present invention.

FIG. 9 is a diagram illustrating the relationship between the first distance Lx and the maximum ripple magnitude in the first example embodiment of the present invention and the comparative example.

FIG. 10 is a diagram illustrating the relationship between the ratio (Ly/La)×100 and the maximum ripple magnitude in the first example embodiment of the present invention and the comparative example.

FIG. 11 is a diagram illustrating the relationship between the absolute value |θ_{c}| of an angle θ_{c} and the duty ratio in the IDT electrode according to the first example embodiment of the present invention.

FIG. 12 is a schematic plan view for explaining the configuration of a first IDT electrode in a first modification of the first example embodiment of the present invention.

FIG. 13 is a schematic plan view of the first IDT electrode in a second modification of the first example embodiment of the present invention.

FIG. 14 is a schematic plan view of the first IDT electrode in a third modification of the first example embodiment of the present invention.

FIG. 15 is a schematic plan view of the first IDT electrode in a fourth modification of the first example embodiment of the present invention.

FIG. 16 is a schematic plan view of the first IDT electrode in a fifth modification of the first example embodiment of the present invention.

FIG. 17 is a schematic plan view of an acoustic wave device according to a sixth modification of the first example embodiment of the present invention.

FIG. 18 is a schematic plan view of an acoustic wave device according to a seventh modification of the first example embodiment of the present invention.

FIG. 19 is a schematic plan view of an acoustic wave device according to a second example embodiment of the present invention.

FIG. 20 is a schematic plan view of an acoustic wave device according to a third example embodiment of the present invention.

FIG. 21 is a diagram illustrating the relationship between the first distance Lx and the maximum ripple magnitude in the case where a first proximal electrode finger of a first resonator electrode and a second proximal electrode finger of a second resonator electrode face each other and are positioned on their respective inner sides.

FIG. 22 is a schematic plan view of an acoustic wave device according to a fourth example embodiment of the present invention.

FIG. 23 is a diagram illustrating the relationship between the ratio (Ly/La)×100 and the maximum ripple magnitude in the case where a first proximal electrode finger of a first resonator electrode and a second proximal electrode finger of a second resonator electrode face each other and are positioned on their respective inner sides.

FIG. 24 is a schematic plan view of an acoustic wave device according to a first modification of the fourth example embodiment of the present invention.

FIG. 25 is a schematic plan view of an acoustic wave device according to a second modification of the fourth example embodiment of the present invention.

FIG. 26 is a schematic plan view of an acoustic wave device according to a fifth example embodiment of the present invention.

FIG. 27 is a schematic plan view of an acoustic wave device according to a modification of the fifth example embodiment of the present invention.

FIG. 28 is a schematic plan view of an acoustic wave device according to a sixth example embodiment of the present invention.

FIG. 29 is a schematic plan view of an acoustic wave device according to a seventh example embodiment of the present invention.

FIG. 30 is a schematic plan view of an acoustic wave device according to an eighth example embodiment of the present invention.

FIG. 31 is a schematic plan view of an acoustic wave device according to a ninth example embodiment of the present invention.

FIG. 32 is a schematic plan view of an acoustic wave device according to a tenth example embodiment of the present invention.

FIG. 33 is a schematic plan view of an acoustic wave device according to an eleventh example embodiment of the present invention.

FIG. 34 is a schematic plan view of an acoustic wave device according to a twelfth example embodiment of the present invention.

FIG. 35 is a schematic plan view of an acoustic wave device according to a thirteenth example embodiment of the present invention.

FIG. 36 is a schematic plan view of an acoustic wave device according to a fourteenth example embodiment of the present invention.

FIG. 37 is a schematic plan view of an acoustic wave device according to a modification of the fourteenth example embodiment of the present invention.

FIG. 38 is a schematic plan view of an acoustic wave device according to a fifteenth example embodiment of the present invention.

FIG. 39 is a schematic plan view of an acoustic wave device according to a sixteenth example embodiment of the present invention.

FIG. 40 is a schematic plan view of an acoustic wave device according to a seventeenth example embodiment of the present invention.

FIG. 41 is a schematic elevational cross-sectional view of an acoustic wave device according to an eighteenth example embodiment of the present invention.

FIG. 42 is a schematic elevational cross-sectional view of an acoustic wave device according to a first modification of the eighteenth example embodiment of the present invention.

FIG. 43 is a schematic elevational cross-sectional view of an acoustic wave device according to a second modification of the eighteenth example embodiment of the present invention.

FIG. 44 is a schematic elevational cross-sectional view of an acoustic wave device according to a nineteenth example embodiment of the present invention.

FIG. 45 is a schematic elevational cross-sectional view of an acoustic wave device according to a twentieth example embodiment of the present invention.

FIG. 46 is a schematic elevational cross-sectional view of an acoustic wave device according to a first modification of the twentieth example embodiment of the present invention.

FIG. 47 is a schematic elevational cross-sectional view of an acoustic wave device according to a second modification of the twentieth example embodiment of the present invention.

FIG. 48 is a schematic elevational cross-sectional view of an acoustic wave device according to a third modification of the twentieth example embodiment of the present invention.

FIG. 49 is a circuit diagram of an acoustic wave device according to a twenty-first example embodiment of the present invention.

FIG. 50 is a simplified plan view of an acoustic wave device according to a twenty-second example embodiment of the present invention.

### DETAILED DESCRIPTION OF THE EXAMPLE EMBODIMENTS

Hereinafter, the present invention will be disclosed by describing example embodiments of the present invention with reference to the drawings.

Each example embodiment described in this specification is illustrative and partial substitutions or combinations of the configurations are possible between different example embodiments.

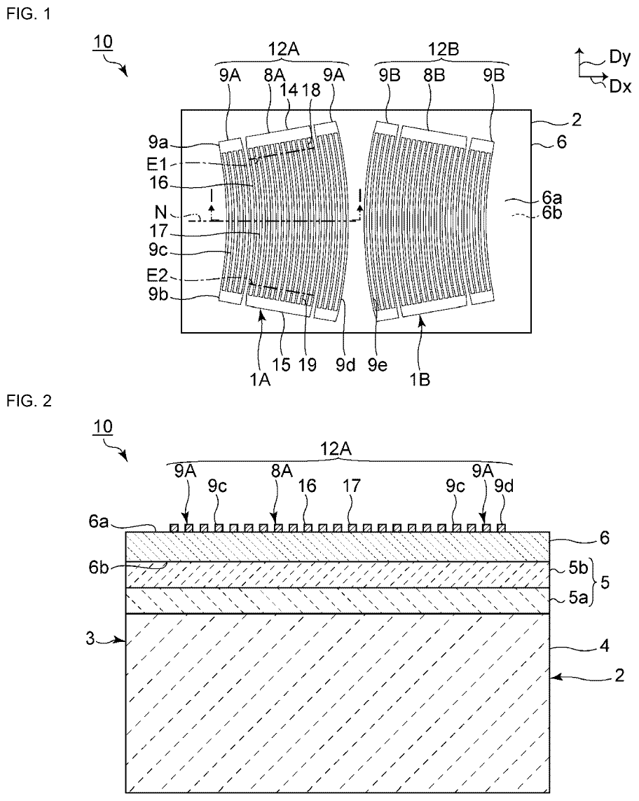

FIG. 1 is a schematic plan view of an acoustic wave device according to a first example embodiment of the present invention. FIG. 2 is a schematic sectional view along a line I-I in FIG. 1. In FIG. 1, wiring lines are omitted. The same applies to the schematic plan views other than FIG. 1.

An acoustic wave device 10 illustrated in FIG. 1 is provided as a portion of a filter device. The acoustic wave device 10 includes a first acoustic wave resonator 1A and a second acoustic wave resonator 1B. The acoustic wave device according to the present example embodiment may be a filter device, for example. The acoustic wave device according to the present example embodiment includes at least two acoustic wave resonators.

As illustrated in FIG. 2, the acoustic wave device 10 includes a piezoelectric substrate 2. The piezoelectric substrate 2 is a multilayer substrate including a piezoelectric layer 6. That is, the piezoelectric substrate 2 is a substrate having piezoelectric properties. Specifically, the piezoelectric substrate 2 includes a support 3 and the piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. The layer structure of the piezoelectric substrate 2 is not limited to that described above. For example, the intermediate layer 5 may include a single dielectric layer. Alternatively, the piezoelectric substrate 2 may be a substrate including only the piezoelectric layer 6.

In the first example embodiment, the support substrate 4 is made of silicon, for example. The first layer 5a is made of silicon nitride, for example. The second layer 5b is made of silicon oxide, for example. The piezoelectric layer 6 is made of 55° rotated Y cut X propagation lithium tantalate, for example. In the piezoelectric layer 6, the direction in which the propagation axis extends is the X-propagation direction. Hereinafter, the direction in which the propagation axis extends is referred to as a first direction Dx, and the perpendicular or substantially perpendicular direction to the first direction Dx is referred to as a second direction Dy. The material of each layer of the piezoelectric substrate 2 is not limited to those described above.

The piezoelectric layer 6 includes a first main surface 6a and a second main surface 6b. The first main surface 6a and the second main surface 6b face each other. Of the first main surface 6a and the second main surface 6b, the second main surface 6b is positioned closer to the support substrate 4. On the first main surface 6a of the piezoelectric layer 6, a first resonator electrode 12A is provided. The first acoustic wave resonator 1A, which is illustrated in FIG. 1, is thus provided.

The first resonator electrode 12A includes a first IDT electrode 8A and a pair of first reflectors 9A. The pair of first reflectors 9A face each other across the first IDT electrode 8A. The first IDT electrode 8A and the first reflectors 9A each include a plurality of electrode fingers. More specifically, the plurality of electrode fingers of the first IDT electrode 8A include a plurality of first electrode fingers 16 and a plurality of second electrode fingers 17. The plurality of electrode fingers of each first reflector 9A include a plurality of reflector electrode fingers 9c as illustrated in FIG. 2.

Back to FIG. 1, the first IDT electrode 8A includes a pair of busbars. Specifically, the pair of busbars include a first busbar 14 and a second busbar 15. The first busbar 14 and the second busbar 15 face each other. One end of each of the plurality of first electrode fingers 16 is connected to the first busbar 14. One end of each of the plurality of second electrode fingers 17 is connected to the second busbar 15. The plurality of first electrode fingers 16 and the plurality of second electrode fingers 17 each include a proximal end portion and a distal end portion. The proximal end portions of the first electrode fingers 16 are portions connected to the first busbar 14. The proximal end portions of the second electrode fingers 17 are portions connected to the second busbar 15. The plurality of first electrode fingers 16 and the plurality of second electrode fingers 17 are interdigitated with each other.

Hereinafter, the first electrode fingers 16, the second electrode fingers 17, and the reflector electrode fingers 9c may be referred to simply as electrode fingers. The first busbar 14 and the second busbar 15 may be referred to simply as a busbar. In the first acoustic wave resonator 1A, the pair of reflectors face each other across the first IDT electrode 8A in the direction in which the plurality of electrode fingers are arranged.

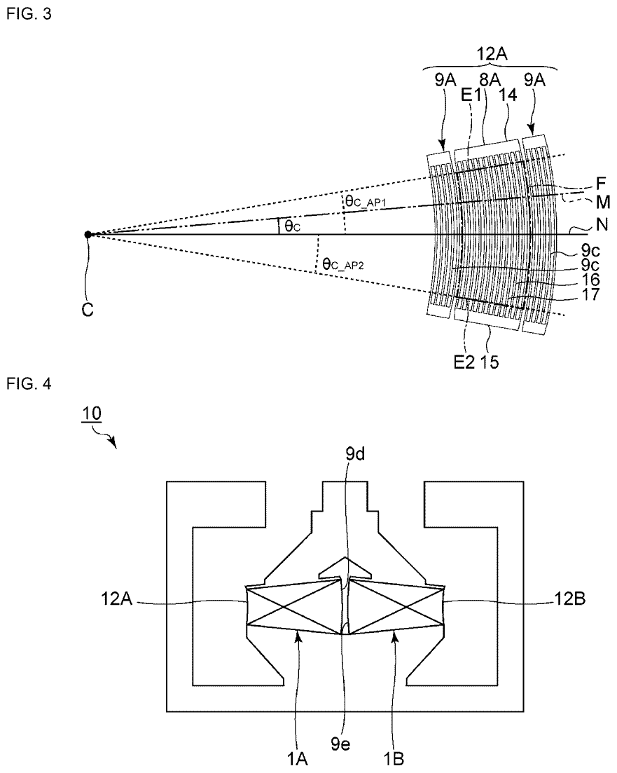

FIG. 3 is a schematic plan view for explaining the configuration of the first IDT electrode in the first example embodiment.

The virtual line connecting the tips of the plurality of second electrode fingers 17 of the first IDT electrode 8A is referred to as a first envelope E1. The virtual line connecting the tips of the plurality of first electrode fingers 16 is referred to as a second envelope E2. The region between the first envelope E1 and the second envelope E2 is referred to as an intersecting region F of the first IDT electrode 8A.

More specifically, the intersecting region F is the region bounded by the first envelope E1 and the second envelope E2, as well as by, among the plurality of electrode fingers of the first IDT electrode 8A, the electrode finger at one end and the electrode finger at the other end in the direction in which the plurality of electrode fingers are arranged. The first envelope E1 corresponds to the edge of the intersecting region F closer to the first busbar 14. The second envelope E2 corresponds to the edge of the intersecting region F closer to the second busbar 15. In the intersecting region F, adjacent electrode fingers overlap each other when viewed in the direction in which the plurality of electrode fingers are arranged. In the intersecting region F, adjacent electrode fingers overlap each other when viewed in the direction in which the first envelope E1 or the second envelope E2 extends. Applying alternating-current voltage to the first IDT electrode 8A allows acoustic waves to be excited in the intersecting region F.

In the first example embodiment, the first envelope E1 and the second envelope E2 are disposed symmetrically with respect to the axis of symmetry passing through the center of the intersecting region F. This axis of symmetry extends in the right-left direction in FIG. 3. The arrangement of the first envelope E1 and the second envelope E2 is not limited to that described above.

Back to FIG. 1, the pair of first reflectors 9A each includes a first reflector busbar 9a and a second reflector busbar 9b. One end of each of the plurality of reflector electrode fingers 9c is connected to the first reflector busbar 9a. The other end thereof is connected to the second reflector busbar 9b.

In the first IDT electrode 8A of the first resonator electrode 12A of the acoustic wave device 10, the electrode finger pitch is constant. The electrode finger pitch of the IDT electrode refers to the distance between the centers of each first electrode finger and the second electrode finger adjacent thereto. The reflector electrode finger pitch refers to the distance between the centers of adjacent reflector electrode fingers. λ=2p where p is the electrode finger pitch of the IDT electrode and λ is the wavelength determined by the electrode finger pitch p.

The first resonator electrode 12A is a curved resonator electrode. In the curved resonator electrode, each of the plurality of electrode fingers has a curved shape in plan view. The plan view in this specification refers to a view from a direction corresponding to the upper side of FIG. 2. In FIG. 2, for example, of the support substrate 4 side and the piezoelectric layer 6 side, the piezoelectric layer 6 side is the upper side.

Specifically, as illustrated in FIG. 3, in the first resonator electrode 12A, in plan view, the plurality of electrode fingers have shapes corresponding to circular arcs of respective concentric circles. More specifically, the plurality of electrode fingers of the first IDT electrode 8A and the plurality of reflector electrode fingers 9c of each first reflector 9A have shapes in plan view corresponding to circular arcs of respective concentric circles. The centers of the circles including the circular arcs in the plurality of electrode fingers, therefore, coincide with each other. The centers are referred to as a fixed point C.

The shapes of the plurality of electrode fingers of the first resonator electrode 12A are not limited to those described above. It is sufficient for the shapes of the plurality of electrode fingers of the first IDT electrode 8A in plan view to include a curved shape in the intersecting region F. It is sufficient for the shapes of the plurality of reflector electrode fingers 9c in plan view to include a curved shape. In plan view, the shapes of the plurality of electrode fingers of the first resonator electrode 12A may be, for example, elliptical arcs, or other curved shapes that are neither circular nor elliptical arcs.

The convex side in the direction in which the plurality of electrode fingers are arranged, of a portion of an electrode finger with the curved shape is defined as an outer side of the portion including the curved shape. The concave side in the direction in which the plurality of electrode fingers are arranged is defined as an inner side of the portion including the curved shape. The outer sides of the plurality of electrode fingers of the first resonator electrode 12A correspond to the right sides in FIGS. 1 and 3. The inner sides of the first resonator electrode 12A correspond to the left sides in FIGS. 1 and 3.

In the first example embodiment, the intersecting region F includes only one curved-line region. As illustrated in FIG. 3, in the curved-line region of the first resonator electrode 12A of the acoustic wave device 10, each of the plurality of first electrode fingers 16 and the plurality of second electrode fingers 17 has a single circular arc shape in plan view. In the curved-line region, each electrode finger may have a single elliptical arc shape in plan view, for example. In the curved-line region, the outer sides of all of the electrode fingers in plan view are oriented in the same direction. In example embodiments of the present invention, the intersecting region F may include a plurality of the curved-line regions.

On the piezoelectric substrate 2, another resonator electrode is provided in addition to the first resonator electrode 12A. In the first example embodiment, each resonator electrode includes an IDT electrode and a pair of reflectors. More specifically, as illustrated in FIG. 1, a second resonator electrode 12B is provided on the piezoelectric substrate 2. The above-described second acoustic wave resonator 1B is thus provided. The second resonator electrode 12B includes a second IDT electrode 8B and a pair of second reflectors 9B. The second resonator electrode 12B is the curved resonator electrode. The outer sides of the plurality of electrode fingers of the second resonator electrode 12B correspond to the left sides in FIG. 1. The inner sides of the plurality of electrode fingers of the second resonator electrode 12B correspond to the right sides in FIG. 1. In the first example embodiment, the wavelengths A of the first IDT electrode 8A and the second IDT electrode 8B are the same or substantially the same. However, the wavelengths A of the first IDT electrode 8A and the second IDT electrode 8B may be different from each other.

The first resonator electrode 12A and the second resonator electrode 12B face each other. More specifically, the second resonator electrode 12B is positioned on the outer sides of the plurality of electrode fingers of the first resonator electrode 12A. The first resonator electrode 12A is positioned on the outer sides of the plurality of electrode fingers of the second resonator electrode 12B. There are no other resonators, electrodes, and wiring between the first resonator electrode 12A and the second resonator electrode 12B. That is, the first resonator electrode 12A and the second resonator electrode 12B are positioned adjacent to each other.

At least one of the first resonator electrode 12A and the second resonator electrode 12B needs to be the curved resonator electrode. In example embodiments of the present invention, for example, it is sufficient that, on the outer side of one of the first resonator electrode 12A and the second resonator electrode 12B that is the curved resonator electrode, the other resonator electrode is positioned. That is, for example, a curved resonator electrode and a linear resonator electrode may face each other, and the linear resonator electrode may be positioned on the outer side of the curved resonator electrode. In this specification, the linear resonator electrode refers to a resonator electrode in which each electrode finger has a straight shape in plan view.

Among the plurality of electrode fingers of the first resonator electrode 12A, the electrode finger positioned closest to the second resonator electrode 12B is referred to as a first proximal electrode finger 9d. In the first example embodiment, the first proximal electrode finger 9d is an electrode finger positioned closest to the second resonator electrode 12B among the reflector electrode fingers 9c of the first reflectors 9A. On the other hand, among the plurality of electrode fingers of the second resonator electrode 12B, the electrode finger positioned closest to the first resonator electrode 12A is referred to as a second proximal electrode finger 9e. Specifically, the second proximal electrode finger 9e is an electrode finger positioned closest to the first resonator electrode 12A among the reflector electrode fingers of the second reflectors 9B.

The outer side of a portion of the first proximal electrode finger 9d that is the closest to the second proximal electrode finger 9e corresponds to the right side in FIG. 1. The second proximal electrode finger 9e is positioned on the outer side of the portion of the first proximal electrode finger 9d. The outer side of a portion of the second proximal electrode finger 9e that is the closest to the first proximal electrode finger 9d corresponds to the left side in FIG. 1. The first proximal electrode finger 9d is positioned on the outer side of the portion of the second proximal electrode finger 9e.

In the first example embodiment, 1) the plurality of resonator electrodes include the first resonator electrode 12A and the second resonator electrode 12B and both the first resonator electrode 12A and the second resonator electrode 12B are the curved resonator electrodes, and 2) the second resonator electrode 12B is positioned on the outer sides of the plurality of electrode fingers of the first resonator electrode 12A while the first resonator electrode 12A is positioned on the outer sides of the plurality of electrode fingers of the second resonator electrode 12B.

With the acoustic wave device 10 of the present example embodiment including the configurations 1) and 2) described above, acoustic coupling between the acoustic wave resonators can be reduced or prevented, and the degradation of the electrical characteristics of the acoustic wave device 10 can be reduced or prevented. This is described below.

With the acoustic wave device 10 including the configuration 1), spurious waves can be reduced or prevented. However, the inventors of example embodiments of the present invention have discovered that in an acoustic wave resonator including the curved resonator electrode, acoustic waves tend to leak toward the inner sides of the plurality of electrode fingers. When another resonator is placed near an acoustic wave resonator including a curved IDT electrode, the modes of the resonators may interfere with each other and may be acoustically coupled.

Furthermore, the inventors of example embodiments of the present invention have discovered that in an acoustic wave resonator including the curved resonator electrode, acoustic waves are less likely to leak toward the outer sides of the plurality of electrode fingers. The acoustic wave device 10 includes the configuration 2). That is, the first resonator electrode 12A and the second resonator electrode 12B face each other on their outer sides. More specifically, the first proximal electrode finger 9d and the second proximal electrode finger 9e face each other and are positioned on their respective outer sides. Therefore, the acoustic waves excited in the first acoustic wave resonator 1A are less likely to leak toward the second acoustic wave resonator 1B. Similarly, acoustic waves excited in the second acoustic wave resonator 1B are less likely to leak toward the first acoustic wave resonator 1A. It is therefore possible to reduce or prevent the acoustic coupling between the first acoustic wave resonator 1A and the second acoustic wave resonator 1B and thus reduce or prevent the degradation of the electrical characteristics of the acoustic wave device 10.

The following description illustrates the advantageous effects of the first example embodiment in detail by comparing the first example embodiment with a comparative example.

FIG. 4 is a simplified plan view illustrating an example of the wiring configuration of the acoustic wave device according to the first example embodiment. FIG. 4 illustrates each acoustic wave resonator by a simplified diagram including two diagonals added to a shape representing the outer perimeter of the acoustic wave resonator. The same applies to simplified plan views, other than FIG. 4.

In the example illustrated in FIG. 4, the first acoustic wave resonator 1A and the second acoustic wave resonator 1B correspond to parallel arm resonators in a ladder filter, for example. Specifically, one busbar of the first acoustic wave resonator 1A and one busbar of the second acoustic wave resonator 1B are connected in common to the same signal potential. The other busbar of the first acoustic wave resonator 1A and the other busbar of the second acoustic wave resonator 1B are connected in common to the ground potential. More specifically, the first acoustic wave resonator 1A and the second acoustic wave resonator 1B correspond to divided resonators connected in parallel.

Herein, in regard to the distance between the first proximal electrode finger 9d of the first resonator electrode 12A and the second proximal electrode finger 9e of the second resonator electrode 12B, a first distance and a second distance are defined as follows. The first distance is denoted by Lx, and the second distance is denoted by Ly.

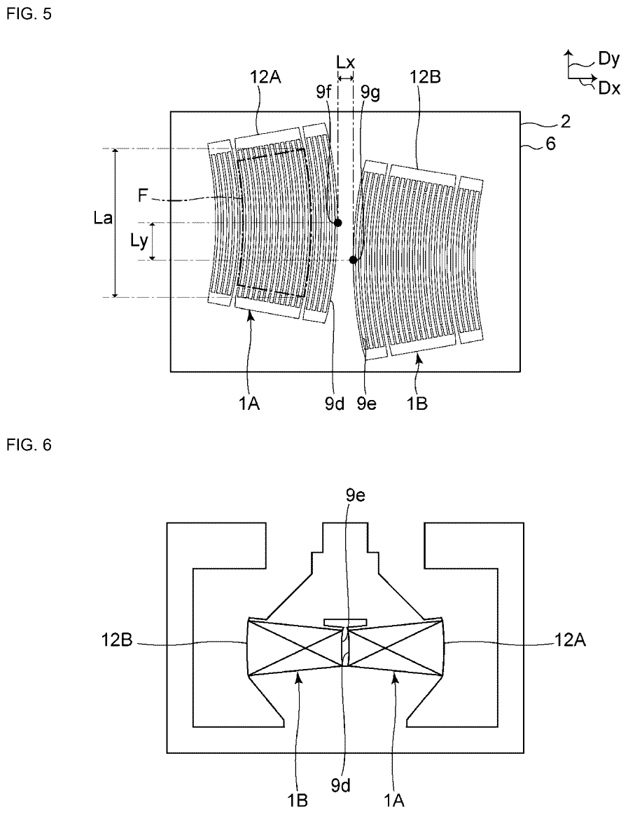

FIG. 5 is a schematic plan view of the acoustic wave device for explaining the first distance Lx and the second distance Ly.

As described above, the direction in which the propagation axis extends in the piezoelectric layer 6 is referred to as the first direction Dx, and the perpendicular or substantially perpendicular direction to the first direction Dx is referred to as the second direction Dy. The first distance Lx is the distance in the first direction Dx between the portion of the first proximal electrode finger 9d that is the closest to the second proximal electrode finger 9e in the first direction Dx and the portion of the second proximal electrode finger 9e that is the closest to the first proximal electrode finger 9d in the first direction Dx. More specifically, the first distance Lx is a component in the first direction Dx of the distance between the portion of the first proximal electrode finger 9d that is the closest to the second proximal electrode finger 9e in the first direction Dx and the portion of the second proximal electrode finger 9e that is the closest to the first proximal electrode finger 9d in the first direction Dx.

The center portion of the first proximal electrode finger 9d in the second direction Dy is referred to as a first center portion 9f. The center portion of the second proximal electrode finger 9e in the second direction Dy is referred to as a second center portion 9g. The second distance Ly is the distance in the second direction Dy, between the first center portion 9f of the first proximal electrode finger 9d and the second center portion 9g of the second proximal electrode finger 9e. More specifically, the second distance Ly is the component in the second direction Dy of the distance between the first center portion 9f and the second center portion 9g. In the acoustic wave device 10 illustrated in FIG. 4, the second distance Ly is 0, for example. However, the second distance Ly is not limited to 0.

The wavelength λ is used as the reference for the first distance Lx and the second distance Ly. Herein, the first envelope E1 and the second envelope E2 in the first resonator electrode 12A are disposed so as to be at least partially symmetric with respect to the axis of symmetry. The wavelength A in the area through which the axis of symmetry passes is used as the reference for the first distance Lx and the second distance Ly. In the first example embodiment illustrated in FIG. 4, the first distance Lx is not particularly limited, and the second distance Ly is 0, for example.

The comparative example differs from the first example embodiment in that, as illustrated in FIG. 6, the first proximal electrode finger 9d and the second proximal electrode finger 9e face each other and are positioned on their respective inner sides. The first distance Lx is, for example, shorter than about 32λ, and the second distance Ly is 0, for example. The return loss of the acoustic wave device 10 illustrated in FIG. 4 and the acoustic wave device of the comparative example was measured.

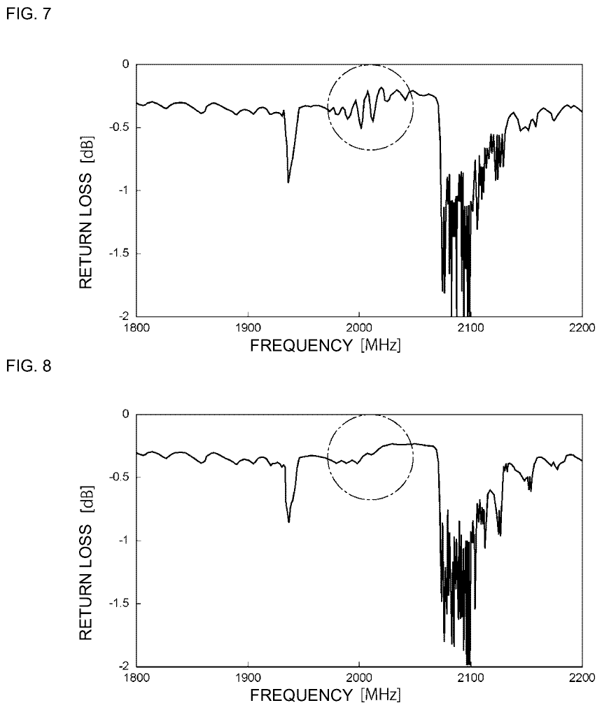

FIG. 7 is a diagram illustrating the return loss in the comparative example. FIG. 8 is a diagram illustrating the return loss in the first example embodiment.

In the comparative example, it is revealed that the return loss is degraded in the vicinity of frequencies circled by the dotted-dashed line in FIG. 7. In the first example embodiment, it is revealed that the degradation of the return loss is reduced in the vicinity of frequencies circled by the dotted-dashed line in FIG. 8.

In the comparative example, acoustic waves excited in the first acoustic wave resonator 1A illustrated in FIG. 6 leak toward the second acoustic wave resonator 1B and reach the second acoustic wave resonator 1B. Similarly, acoustic waves excited in the second acoustic wave resonator 1B leak toward the first acoustic wave resonator 1A and reach the first acoustic wave resonator 1A. Therefore, the first acoustic wave resonator 1A and the second acoustic wave resonator 1B are acoustically coupled, resulting in degradation of return loss.

In the first example embodiment, the second acoustic wave resonator 1B is positioned on the outer side of the first proximal electrode finger 9d in the first acoustic wave resonator 1A, which is illustrated in FIG. 1. Acoustic waves excited in the first acoustic wave resonator 1A are therefore less likely to leak toward the second acoustic wave resonator 1B. Similarly, the first acoustic wave resonator 1A is positioned on the outer side of the second proximal electrode finger 9e in the second acoustic wave resonator 1B. Acoustic waves excited in the second acoustic wave resonator 1B are therefore less likely to leak toward the first acoustic wave resonator 1A. It is therefore possible to reduce or prevent the acoustic coupling between the first acoustic wave resonator 1A and the second acoustic wave resonator 1B and thus reduce or prevent the degradation of the electrical characteristics, such as the return loss, of the acoustic wave device 10.

The first example embodiment is described in more detail below. The first acoustic wave resonator 1A and the second acoustic wave resonator 1B have the same or substantially the same configuration, except that the outer sides thereof face opposite directions to each other. The following description then illustrates the configuration of the first acoustic wave resonator 1A in more detail. Preferred configurations in the first acoustic wave resonator 1A illustrated below are also preferred configurations in the second acoustic wave resonator 1B.

As illustrated in FIG. 3, in the first example embodiment, the straight line corresponding to the axis of symmetry with respect to which the first envelope E1 and the second envelope E2 are symmetric is referred to as a reference line N. The reference line N passes through the fixed point C. The reference line N does not need to pass through the fixed point C. In example embodiments of the present invention, a plurality of the reference lines N may be defined.

In the first example embodiment illustrated in FIG. 1, each of the plurality of electrode fingers of the first IDT electrode 8A has a circular arc shape in plan view as described above. Herein, the elliptical coefficient of a circle or ellipse including the arc in the shape of each of the plurality of electrode fingers is denoted by α2/α1. The elliptical coefficient α2/α1 is, for example, about 1 in the first example embodiment. When the arc in the shape of each of the plurality of electrode fingers is included in an ellipse, the elliptical coefficient α2/α1 is not equal to 1. Herein, al corresponds to the dimension of the ellipse along its major or minor axis that passes through the intersecting region F while α2 corresponds to the dimension of the ellipse along its major or minor axis that does not pass through the intersecting region F. The formula of the elliptical coefficient in X-Y plane is expressed as: (x/α1) 2+ (y/α2)²=r² where r is any constant.

Each electrode finger of the first IDT electrode 8A includes a pair of edge portions connecting the proximal end portion and the distal end portion in plan view. Both edge portions are curved. In this specification, the direction in which each electrode finger extends is as follows, unless otherwise noted. When a virtual line segment parallel or substantially parallel to the reference line N is drawn at any given portion of the electrode finger so as to connect both edge portions, the centroid of the portion positioned on the virtual line segment is defined as a representative point of the virtual line segment. On the electrode finger, an infinite number of the virtual line segments can be drawn, and there are an infinite number of the representative points. The direction in which each electrode finger extends is defined as the direction of the tangent to the curved line connecting these representative points. The direction in which the electrode finger extends varies at each position in the electrode finger. For example, when the intersecting region F includes more than one curved-line region and each curved-line region includes a different reference line N, each virtual line segment should be extended in the direction parallel or substantially parallel to the reference line N of the curved-line region in which this virtual line segment is drawn.

The piezoelectric layer 6 illustrated in FIG. 1 is made of 55° rotated Y cut X propagation lithium tantalate, for example. In such a manner, the material of the piezoelectric layer 6 includes a piezoelectric single crystal. In the piezoelectric layer 6, the propagation axis extends in the direction of X-propagation. The direction in which the propagation axis extends is not limited to that described above and may be, for example, the direction of about 90° X propagation in the piezoelectric layer 6. Alternatively, the direction in which the propagation axis extends may be perpendicular or substantially perpendicular to the direction in which any portion of the electrode fingers of the first IDT electrode 8A extends.

The reference line N extends parallel or substantially parallel to the first direction Dx. The direction in which the reference line N extends is not limited to that described above. The direction in which the reference line N extends may intersect the first direction Dx.

As illustrated in FIG. 3, the angle between a straight line passing through the fixed point C and the reference line N is denoted by θ_{c}. An infinite number of straight lines pass through the fixed point C, and FIG. 3 illustrates examples of such straight lines. In this specification, the positive direction of the angle θ_{c} is defined as the counterclockwise direction in plan view. More specifically, the positive direction is the direction from the second busbar 15 toward the first busbar 14.

The intersecting region F in the first IDT electrode 8A includes portions positioned on the infinite number of straight lines passing through the fixed point C. FIG. 3 illustrates a straight line M as an example of the infinite number of straight lines passing through the fixed point C and the intersecting region F. For example, acoustic waves are excited in the portion positioned on the straight line M in the intersecting region F. Acoustic waves are also excited in the portions positioned on the infinite number of the other, not-illustrated straight lines passing through the fixed point C and the intersecting region F. That is, the first acoustic wave resonator 1A includes excitation portions positioned on the straight line M and excitation portions positioned on an infinite number of the other, not-illustrated straight lines.

The direction in which acoustic waves are excited in the intersecting region F is any one of the following three directions. The first direction is perpendicular or substantially perpendicular to the direction in which each electrode finger extends. The second direction is the direction of the shortest line connecting adjacent electrode fingers. The third direction is parallel or substantially parallel to the electric field vector generated between electrode fingers.

The angle between the reference line N and the excitation direction of an acoustic wave at an intersection of an electrode finger and a straight line passing through the fixed point C and an excitation portion in the intersecting region F is referred to as an excitation angle θ_{c_prop}. In the first example embodiment, the excitation direction of acoustic waves is the first direction. In the excitation portion through which the reference line N passes, the angle θ_{c} and the excitation angle θ_{c_prop} are about 0°, for example.

When the elliptical coefficient α2/α1 is about 1, for example, that is, when the electrode finger shape is a circular arc, the angle θ_{c} is equal or substantially equal to the excitation angle θ_{c_prop}. On the other hand, when the electrode finger shape is other than a circular arc, the angle θ_{c} is not equal or substantially equal to the excitation angle θ_{c_prop}. However, the angle θ_{c} is equal substantially equal to the excitation angle θ_{c_prop}. It should be noted that there is no significant difference between the angle θ_{c} and the excitation angle θ_{c_prop} that would override the operation or its advantageous effects.

The excitation portions differ in the excitation angle θ_{c_prop} and exhibit different acoustic wave propagation characteristics. Therefore, spurious waves have different frequencies in different excitation portions. This allows spurious waves and transverse modes outside the pass band to be dispersed and thus reduced or prevented. In this specification, the term “outside the pass band” in an acoustic wave resonator refers to frequencies lower than the resonant frequency and frequencies higher than the anti-resonant frequency.

In addition, the direction in which the first envelope E1 extends and the direction in which the second envelope E2 extends intersect the direction in which the reference line N extends. This enables effective reduction or prevention of the transverse modes.

In the first example embodiment, resonant frequencies or anti-resonant frequencies are the same or substantially the same in all of the excitation portions. Therefore, the resonance characteristics are less likely to be degraded. In this specification, “one frequency is the same or substantially the same as another frequency” means that the absolute value of the difference between both frequencies is, for example, about 2% or less relative to a reference frequency. The reference frequency refers to the frequency when the excitation angle θ_{c_prop} is, for example, about 0°. In the intersecting region F, the absolute value of the difference between the highest and lowest resonant frequencies of the primary mode is, for example, preferably about 1% or less relative to the reference frequency. Alternatively, in the intersecting region F, the absolute value of the difference between the highest and lowest anti-resonant frequencies of the primary mode is, for example, preferably about 1% or less relative to the reference frequency. This enables a more reliable improvement of the resonance characteristics.

The angle θ_{c} between the reference line N and the straight line passing through the fixed point C and the first envelope E1, which is the edge portion of the intersecting region F closer to the first busbar 14, is referred to as an intersecting angle θ_{c_AP1}. The angle θ_{c} between the reference line N and the straight line passing through the fixed point C and the second envelope E2, which is the edge portion of the intersecting region F closer to the second busbar 15, is referred to as an intersecting angle θ_{c_AP2}. In this case, Of θ_{c_AP2}≤θ_{c}≤θ_{c_AP1}. In the first example embodiment, the absolute value of the intersecting angle θ_{c_AP1} is equal or substantially equal to that of the intersecting angle θ_{c_AP2}. The absolute value of the angle θ_{c} satisfies 0°≤|θ_{c}|≤|θ_{c_AP1}|=|θ_{c_AP2}|.

The distance between the first envelope E1 and the second envelope E2 is referred to as an intersecting width. In this specification, the distance includes a distance other than the distance between the closest portions. In the first example embodiment, the intersecting width is based on the normal line to the axis of symmetry with respect to which the first envelope E1 and the second envelope E2 are symmetric. Specifically, the normal line passes through both the first envelope E1 and the second envelope E2. The intersecting width is the distance between the intersection of the normal line and the first envelope E1 and the intersection of the normal line and the second envelope E2.

In the first example embodiment, the axis of symmetry is the reference line N. Both the direction in which the first envelope E1 extends and the direction in which the second envelope E2 extends intersect the direction in which the reference line N extends. The intersecting width of the intersecting region F is therefore not constant. More specifically, the intersecting width in the first IDT electrode 8A increases towards the outer side of each electrode finger. The intersecting region F of the first resonator electrode 12A includes a portion positioned outside of the end portion on the outer side of the first envelope E1. In the portion, the normal line to the axis of symmetry of the first envelope E1 and the second envelope E2 does not pass through the first envelope E1 and the second envelope E2. The intersecting width is therefore not defined in that portion.

Back to FIG. 1, in the first example embodiment, the intersecting width of a portion of the first IDT electrode 8A that is positioned closest to the second resonator electrode 12B is referred to as a proximal intersecting width. In the following, the proximal intersecting width is denoted by La. More specifically, the proximal intersecting width La is the shorter one of the intersecting widths of a portion of the first IDT electrode 8A that is positioned closest to the second resonator electrode 12B and a portion of the second IDT electrode 8B that is positioned closest to the first resonator electrode 12A. In the first example embodiment, both intersecting widths are equal or substantially equal. Therefore, the proximal intersecting width La may be the intersecting width of a portion of the second IDT electrode 8B that is positioned closest to the first resonator electrode 12A.

Herein, the relationship between the distance between the first resonator electrode 12A and the second resonator electrode 12B illustrated in FIG. 1 and the return loss was examined. Specifically, the return loss was measured for each variation of the first distance Lx and the second distance Ly.

As described above, the wavelength λ is used as the reference for the first distance Lx and the second distance Ly. In the first IDT electrode 8A of the acoustic wave device 10, the electrode finger pitch is constant. The wavelength λ in the first IDT electrode 8A is constant regardless of the angle θ_{c}. The same applies to the second IDT electrode 8B. The wavelength λ in the first IDT electrode 8A is equal or substantially equal to that in the second IDT electrode 8B. When the wavelength λ in the first acoustic wave resonator 1A is different from that in the second acoustic wave resonator 1B, the reference for the first distance Lx and the second distance Ly can be, for example, the wavelength λ of the first acoustic wave resonator 1A.

When the electrode finger pitch varies with the angle θ_{c} in the first IDT electrode 8A, for example, the reference for the first distance Lx and the second distance Ly can be the wavelength λ in the portion where the angle θ_{c} is about 0°.

As described above, the return loss was measured for each variation of the first distance Lx and the second distance Ly in the acoustic wave device 10 of the first example embodiment. The magnitude of ripples was calculated in the vicinity of the frequencies circled by the dotted-dashed line in FIG. 8. The magnitude of each ripple was defined as the difference in intensity between the trough and peak of the ripple. Then the maximum ripple magnitude was determined. The first distance Lx was set to, for example, about 6λ or about 31λ. In the acoustic wave device of the comparative example, the maximum ripple magnitude was determined when the first distance Lx was set to about 2.5λ.

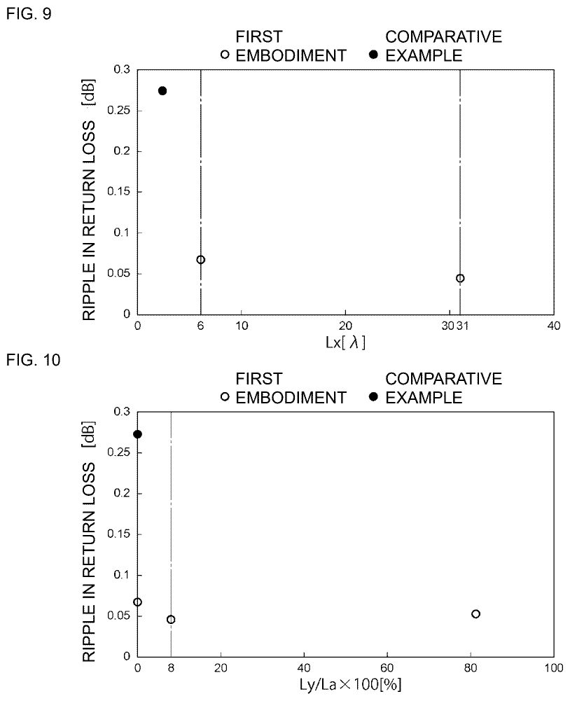

FIG. 9 is a diagram illustrating the relationship between the first distance Lx and the maximum ripple magnitude in the first example embodiment and the comparative example.

As illustrated in FIG. 9, in the first example embodiment, the ripples in the return loss are further reduced or prevented relative to the comparative example. In addition, the longer the first distance Lx, the smaller the ripples. The first distance Lx is, for example, preferably at least about 6λ, more preferably at least about 31λ. This can further reduce or prevent the degradation of the return loss.

As the indicator for the distance in the second direction Dy between the first resonator electrode 12A and the second resonator electrode 12B, a ratio (Ly/La)×100 [%] of the second distance Ly to the proximal intersecting width La is used. During the measurement of the return loss, the second distance Ly was varied while the proximal intersecting width La was constant. The ratio (Ly/La)× 100 [%] was set to about 0%, about 8%, or about 81%. The results of the comparative example are illustrated together.

FIG. 10 is a diagram illustrating the relationship between the ratio (Ly/La)×100 and the maximum ripple magnitude in the first example embodiment and the comparative example.

As illustrated in FIG. 10, the ripples in the return loss are further reduced or prevented in the first example embodiment relative to the comparative example. When the ratio (Ly/La)×100 is greater than about 0%, the ripples are much smaller. Preferably, (Ly/La)×100 [%]>about 0 [%], more preferably, (Ly/La)×100 [%]>about 8 [%]. This can further reduce or prevent the degradation of the return loss.

Back to FIG. 1, the first IDT electrode 8A includes a plurality of offset electrodes. Specifically, the plurality of offset electrodes include a plurality of first offset electrodes 18 and a plurality of second offset electrodes 19. One end of each of the plurality of first offset electrodes 18 is connected to the first busbar 14. The first electrode fingers 16 and the first offset electrodes 18 are alternately arranged. One end of each of the plurality of second offset electrodes 19 is connected to the second busbar 15. The second electrode fingers 17 and the second offset electrodes 19 are alternately arranged.

Similar to the plurality of first electrode fingers 16 and the plurality of second electrode fingers 17, the plurality of first offset electrodes 18 and the plurality of second offset electrodes 19 each include a proximal end portion and a distal end portion. The proximal end portions of the first offset electrodes 18 are portions connected to the first busbar 14. The proximal end portions of the second offset electrodes 19 are portions connected to the second busbar 15.

The distal end portions of the first electrode fingers 16 face the distal end portions of the second offset electrodes 19 across gaps. On the other hand, the distal end portions of the second electrode fingers 17 face the distal end portions of the first offset electrodes 18 across gaps.

Each of the plurality of first offset electrodes 18 and the plurality of second offset electrodes 19 has a curved shape in plan view. More specifically, in plan view, the plurality of first offset electrodes 18 and the plurality of second offset electrodes 19 have shapes corresponding to circular arcs of respective concentric circles. The centers of the circles including the circular arcs in the shapes of the plurality of first offset electrodes 18 and the plurality of second offset electrodes 19, coincide with the fixed point C. In the following, the first offset electrodes 18 and the second offset electrodes 19 may be referred to simply as offset electrodes.

The plurality of offset electrodes do not need to be provided. However, it is preferable that the first IDT electrode 8A includes the plurality of first offset electrodes 18 and the plurality of second offset electrodes 19. This enables the primary mode having propagated from the intersecting region F toward each busbar to be reflected toward the intersecting region F. This can reduce the loss of the primary mode and improve the characteristics of the primary mode.

Preferably, each of the plurality of first offset electrodes 18 in plan view has a curved shape. In this case, the shapes of the first offset electrodes 18 can be configured to match the conditions that correspond to the frequency of the primary mode reflected on the first offset electrodes 18. This can improve the efficiency of reflecting the primary mode, thus effectively improving the characteristics of the primary mode. Similarly, it is preferable that each of the plurality of second offset electrodes 19 in plan view has a curved shape.

Each of the plurality of offset electrodes does not need to have a curved shape in plan view. For example, each of the plurality of offset electrodes may have a straight shape in plan view. In this case, the distance between the distal end portion of each first offset electrode 18 and the first busbar 14 can be shortened. In a similar manner, the distance between the distal end portion of each second offset electrode 19 and the second busbar 15 can be shortened. This can reduce the electric resistance of the first IDT electrode 8A.

The following description illustrates an example of design parameters of the first acoustic wave resonator 1A. In the first example embodiment, the design parameters of the second acoustic wave resonator 1B are the same or substantially the same as those of the first acoustic wave resonator 1A. In this specification, the duty ratio indicates the duty ratio in the intersecting region of an IDT electrode, unless otherwise noted.
Support substrate 4: material, Si; plane orientation, (111); ψ in Euler angles (φ, θ, ψ), about 73°
First layer 5a: material, SiN; thickness, about 0.15λ
Second layer 5b: material, SiO₂; thickness, about 0.15λ
Piezoelectric layer 6: material, 55° rotated Y cut X propagation LiTaO₃; thickness, about 0.2λ
First IDT electrode 8A: material, Al; thickness, about 0.05λ
Number of pairs of electrode fingers of the first IDT electrode 8A: 60 pairs
Elliptical coefficient α2/α1 of the electrode finger shape: 1
Intersecting angle θ_{c_AP1}: about 10°
Intersecting angle θ_{c_AP2}: about −10°
Wavelength λ: about 2 μm
Duty ratio: about 0.5 in the excitation portion where the angle θ_{c} is about 0°.

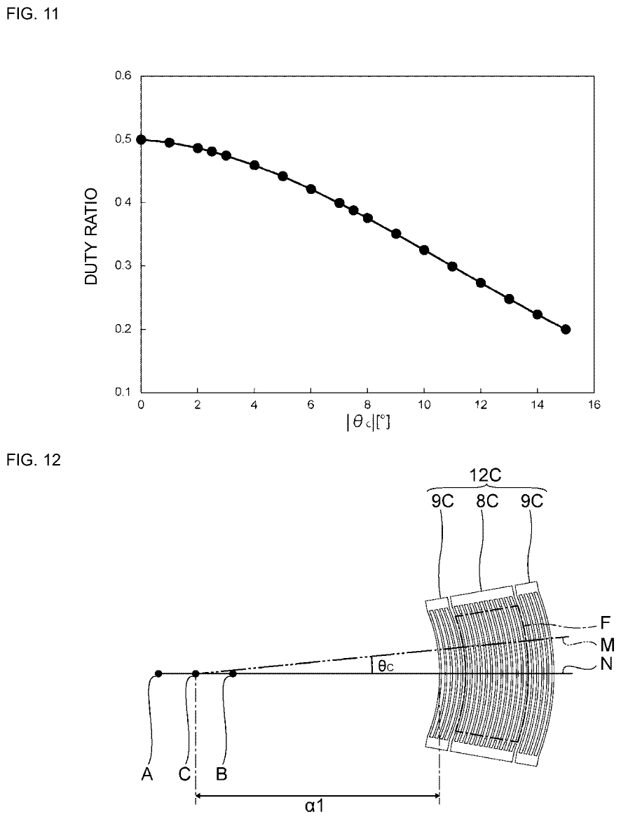

In the first example embodiment, the resonant frequencies or anti-resonant frequencies are the same or substantially the same throughout the entirety of the intersecting region F. Specifically, the duty ratio has different values in multiple excitation portions such that the resonant frequencies or anti-resonant frequencies in all of the excitation portions of the intersecting region F are the same or substantially the same. That is, the duty ratio varies according to the angle θ_{c}. The duty ratio is the same or substantially the same among the excitation portions where the absolute value |θ_{c}| of the angle θ_{c} is equal or substantially equal. Due to the configuration of the first IDT electrode 8A as described above, the resonance characteristics of the first acoustic wave resonator 1A are less likely to be degraded. The relationship between the absolute value |θ_{c}| of the angle θ_{c} and the duty ratio in the first example embodiment is illustrated in FIG. 11.

FIG. 11 is a diagram illustrating the relationship between the absolute value |θ_{c}| of an angle θ_{c} and the duty ratio in the IDT electrode according to the first example embodiment.

In the first example embodiment, the duty ratio is the highest when the angle θ, is about 0°. The duty ratio decreases as the absolute value |θ_{c}| of the angle θ_{c} increases. This allows the resonant frequencies or anti-resonant frequencies to be the same or substantially the same through the entirety or substantially the entirety of the intersecting region F. However, the duty ratio may be constant. In this case, it is preferable that some parameter other than the duty ratio varies according to the angle θ_{c} such that the resonant frequencies or anti-resonant frequencies are the same or substantially the same throughout the entirety of the intersecting region F.

In the first example embodiment, the duty ratio, as the metallization ratio in the region where the plurality of first electrode fingers 16 and the plurality of first offset electrodes 18 are provided, decreases towards the first busbar 14. Similarly, the duty ratio, as the metallization ratio in the region where the plurality of second electrode fingers 17 and the plurality of second offset electrodes 19 are provided, also decreases towards the second busbar 15. However, these duty ratios may be constant.

Preferably, parameters, such as the duty ratio affecting the frequency, the electrode finger pitch, the electrode finger thickness, the thickness of the piezoelectric layer 6, and the thickness of the intermediate layer 5 in the piezoelectric substrate 2, vary according to the angle θ_{c}. When a dielectric film is provided on the piezoelectric substrate 2 so as to cover the IDT electrodes, the thickness of the dielectric film may vary with the angle θ_{c}. Among the parameters, two or more parameters may vary according to the angle θ_{c}. It is preferable that at least one of those parameters varies according to the angle θ_{c} such that the resonant frequencies or anti-resonant frequencies are the same or substantially the same throughout the entirety of the intersecting region F. The resonance characteristics are thus less likely to be degraded.

In each first reflector 9A, similarly, it is preferable that parameters, such as the duty ratio, the electrode finger pitch of the reflector electrode fingers 9c, the electrode finger thickness, the thickness of the piezoelectric layer 6, or the thickness of the intermediate layer 5 in the piezoelectric substrate 2 vary according to the angle θ_{c}. When a dielectric film is provided on the piezoelectric substrate 2 so as to cover each first reflector 9A, the thickness of the dielectric film may vary according to the angle θ_{c}. Among the parameters, two or more parameters may vary according to the angle θ_{c}. For example, it may be assumed that each first reflector 9A defines a portion of the first IDT electrode 8A. In this case, it is preferable that at least one of those parameters varies with the angle θ_{c} so as to correspond to the configuration in which the resonant frequencies or anti-resonant frequencies are the same or substantially the same throughout the entirety or substantially the entirety of the intersecting region F. The resonance characteristics are thus less likely to be degraded. The same applies to the second acoustic wave resonator 1B.

In plan view, the plurality of reflector electrode fingers 9c of each first reflector 9A have shapes corresponding to circular arcs of respective concentric circles. The centers of circles including the circular arcs in the shapes of the plurality of reflector electrode fingers 9c coincide with the fixed point C. The parameters such as the electrode finger pitch of the reflector electrode fingers 9c of each first reflector 9A and the duty ratio may be different from those of the electrode fingers of the first IDT electrode 8A in the intersecting region F. The same applies to the second resonator electrode 12B.

As illustrated in FIG. 2, in the first example embodiment, the piezoelectric substrate 2 is a multilayer substrate including the support substrate 4, the first layer 5a and the second layer 5b of the intermediate layer 5, and the piezoelectric layer 6. More specifically, the first layer 5a in the first example embodiment is a high-velocity film. The high-velocity film is a film with a relatively high acoustic velocity. Still more specifically, the acoustic velocity of bulk waves propagating in the high-velocity film is higher than that of acoustic waves propagating in the piezoelectric layer 6. On the other hand, the second layer 5b is a low-velocity film. The low-velocity film is a film with a relatively low acoustic velocity. Still more specifically, the acoustic velocity of bulk waves propagating in the low-velocity film is lower than that of bulk waves propagating in the piezoelectric layer 6.

In the first example embodiment, the high-velocity film, the low-velocity film, and the piezoelectric layer 6 are laminated in this order in the piezoelectric substrate 2. This allows acoustic waves to be effectively confined on the piezoelectric layer 6 side.

Examples of the material of the high-velocity film include, for example, piezoelectric materials such as aluminum nitride, lithium tantalate, lithium niobate, or quartz crystal, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, and semiconductors such as silicon, and materials including the materials as the main component. The spinel above includes, for example, an aluminum compound including oxygen and one or more of Mg, Fe, Zn, Mn, or other elements. Examples of such spinel are MgAl₂O₄, FeAl₂O₄, ZnAl₂O₄, or MnAl₂O₄. In this specification, the main component refers to a component including more than 50 wt %. The material of the main component may exist in a single-crystal, polycrystalline, or amorphous configuration, or a mixed form thereof.

Examples of the material of the low-velocity film include dielectrics, such as glass, silicon oxide, silicon oxynitride, lithium oxide, tantalum oxide, or compounds of silicon oxide added with fluorine, carbon, or boron, or materials including the materials as the main component.

Examples of the material of the piezoelectric layer 6 include lithium tantalate, lithium niobate, zinc oxide, aluminum nitride, quartz crystal, or lead zirconate titanate (PZT). Preferably, the material of the piezoelectric layer 6 is, for example, lithium tantalate or lithium niobate.

Examples of the material of the support substrate 4 are piezoelectric materials such as aluminum nitride, lithium tantalate, lithium niobate, or quartz crystal, ceramics such as alumina, sapphire, magnesia, silicon nitride, silicon carbide, zirconia, cordierite, mullite, steatite, or forsterite, dielectrics such as glass or diamond, and semiconductors such as silicon, gallium nitride, or gallium arsenide, resin, or materials including the materials as the main component. The material of the support substrate 4 is, for example, preferably high-resistance silicon. Preferably, the material of the support substrate 4 has a volume resistivity of about 1000 Ω·cm or more, for example.

The material of the first resonator electrode 12A and the second resonator electrode 12B may be, for example, one or more of Ti, Mo, Ru, W, Al, Pt, Ir, Cu, Cr, or Sc. The first resonator electrode 12A and the second resonator electrode 12B may include a single-layer metal film or a multilayer metal film.

In the example illustrated in FIG. 4, the first acoustic wave resonator 1A and the second acoustic wave resonator 1B correspond to the parallel arm resonators in a ladder filter and correspond to the parallel divided resonators. However, the first acoustic wave resonator 1A and the second acoustic wave resonator 1B may be used as acoustic wave resonators other than divided resonators. For example, at least one of the first acoustic wave resonator 1A and the second acoustic wave resonator 1B may be used as a series arm resonator.

The following description illustrates first to fifth modifications of the first example embodiment, which differ from the first example embodiment only in the shape of the first resonator electrode 12A. As in the first example embodiment, the first to fifth modifications enable reduction or prevention of the acoustic coupling between the acoustic wave resonators and a reduction in the degradation of the electrical characteristics.

In the first modification illustrated in FIG. 12, each of a plurality of electrode fingers of a first resonator electrode 12C has an elliptical arc shape in plan view. Specifically, the shapes in plan view of a plurality of electrode fingers of a first IDT electrode 8C and a plurality of reflector electrode fingers of each first reflector 9C correspond to elliptical arcs of respective ellipses each having a fixed point at the same position. The midpoint of foci A and B is the fixed point C. In other words, the fixed point C is the centroid of the foci A and B. In plan view, the elliptical coefficient α2/α1 of the shapes of the plurality of electrode fingers is not equal to 1.

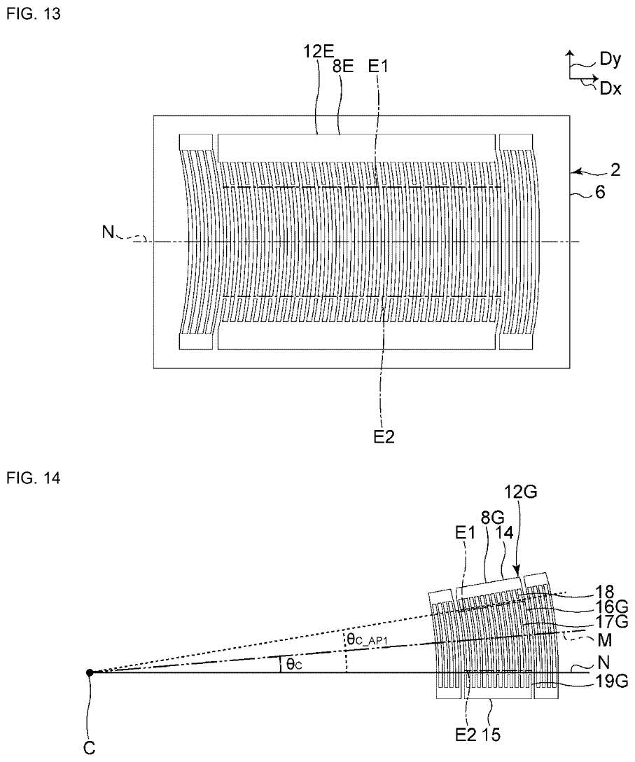

In a first IDT electrode 8E in the second modification illustrated in FIG. 13, the first envelope E1 and the second envelope E2 extend parallel or substantially parallel to each other. The reference line N extends parallel or substantially parallel to the first envelope E1 and the second envelope E2. In the second modification, the intersecting width is constant.

In a first IDT electrode 8G of the third modification illustrated in FIG. 14, in plan view, each of a plurality of second electrode fingers 17G has a straight shape in the region between the second envelope E2 and the second busbar 15. In the other region, each of the plurality of second electrode fingers 17G has a circular arc shape in plan view. Each of a plurality of second offset electrodes 19G has a straight shape in plan view. On the other hand, each of a plurality of first electrode fingers 16G has a circular arc shape in plan view. Each of a plurality of first offset electrodes 18 also has a circular arc shape in plan view.

In the third modification, the reference line N extends parallel or substantially parallel to the second envelope E2. That is, the angle θ_{c} of the portion through which the second envelope E2 passes is about 0°.

In the third modification, the intersecting width is based on a normal line to the second envelope E2. Specifically, the normal line passes through both the first envelope E1 and the second envelope E2. The intersecting width refers to the distance between the intersection of the normal line and the first envelope E1 and the intersection of the normal line and the second envelope E2.

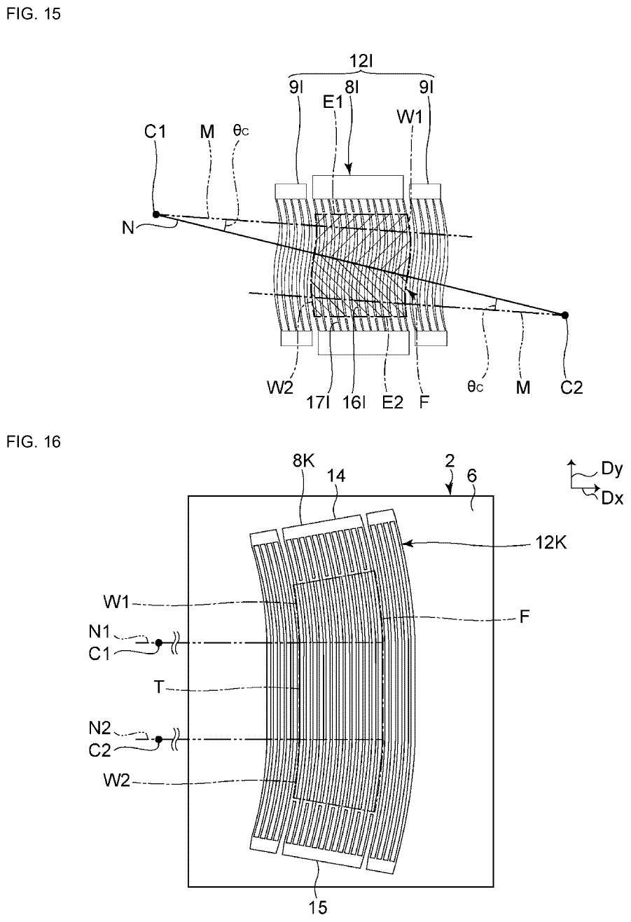

In a first IDT electrode 8I of a fourth modification illustrated in FIG. 15, the shapes in plan view of a plurality of first electrode fingers 16I and a plurality of second electrode fingers 17I each include an inflection point. The inflection point in this specification refers to a point at which different curved lines are connected to each other, or a point at which a curved line is connected to a straight line. When different curved lines are connected to each other at an inflection point, the outer side of the electrode finger differs on either side of the inflection point.

More specifically, in the fourth modification, a portion in which the outer side corresponds to the left in FIG. 15 and a portion in which the outer side corresponds to the right are connected at the inflection point. Thus, in the fourth modification, two curved shapes are inverted with respect to each other across the inflection point. The same applies to each first reflector 91.

In plan view, each of the plurality of electrode fingers in a first resonator electrode 12I has the shape of two connected circular arcs. In plan view, one of the two circular arcs in the shape of each of the plurality of electrode fingers is a circular arc of a corresponding one of a plurality of concentric circles. The centers of the circles including the circular arcs in the shapes of the plurality of electrode fingers coincide with each other. These centers of the circles can be defined as a first fixed point. In plan view, the other circular arc in the shape of each of the plurality of electrode fingers is also a circular arc of a corresponding one of a plurality of concentric circles. The centers of these circles can be defined as a second fixed point. In the present modification, the two fixed points are defined. The two fixed points are opposite to each other across the first IDT electrode 8I.

As described above, in the intersecting region F, the shapes of the plurality of electrode fingers in the first resonator electrode 12I may each include at least two curved portions in which the outer sides are oriented in different directions. In plan view, the shapes of the plurality of electrode fingers may each include at least one inflection point in the intersecting region F.

The intersecting region F of the first IDT electrode 8I includes a plurality of the curved-line regions. Specifically, the plurality of curved-line regions include a first curved-line region W1 and a second curved-line region W2. The first curved-line region W1 includes the first envelope E1. The second curved-line region W2 includes the second envelope E2. In plan view, each of the plurality of first electrode fingers 16I and the plurality of second electrode fingers 17I has a single circular or elliptical arc shape in each curved-line region. In the fourth modification, each of the plurality of electrode fingers has a single circular arc shape in each curved-line region in plan view.

One of the two fixed points is a fixed point C1 defined for the first curved-line region W1. The other fixed point is a fixed point C2 defined for the second curved-line region W2.

In the fourth modification, each excitation portion refers to a portion on any straight line that passes through the fixed point in each curved-line region. The reference line N is a straight line that passes through a boundary between the first curved-line region W1 and the second curved-line region W2 and passes through the two fixed points.

The angle θ_{c} is defined as the angle between the reference line N and a straight line passing through the fixed point for each curved-line region and the curved-line region. In the fourth modification, the resonant frequencies or anti-resonant frequencies are the same or substantially the same throughout the entirety or substantially the entirety of each curved-line region.

In a first IDT electrode 8K of the fifth modification illustrated in FIG. 16, the intersecting region F includes the first curved-line region W1, the second curved-line region W2, and a straight-line region T. The first curved-line region W1, the second curved-line region W2, and the straight-line region T are arranged in the direction in which the first busbar 14 and the second busbar 15 face each other. More specifically, the first curved-line region W1 and the second curved-line region W2 face each other across the straight-line region T.

In the first IDT electrode 8K, each electrode finger includes two inflection points. At each inflection point, an arc and a straight line are connected. The extension line of the boundary between the straight-line region T and the first curved-line region W1 passes through the fixed point C1. In the fifth modification, the straight line including the boundary and the extension line of the boundary is a reference line N1 for the first curved-line region W1. The angle θ_{c} in the first curved-line region W1 is the angle between the reference line N1 and a straight line passing through the fixed point C1 and the first curved-line region W1.

On the other hand, the extension line of the boundary between the straight-line region T and the second curved-line region W2 passes through the fixed point C2. The straight line including the boundary and the extension line of the boundary is a reference line N2 for the second curved-line region W2. The angle θ_{c} in the second curved-line region W2 is the angle between the reference line N2 and a straight line passing through the fixed point C2 and the second curved-line region W2.

In the straight-line region T, the angle corresponding to the angle θ_{c} is constant. More specifically, the angle θ_{c} is about 0° at the boundary between the straight-line region T and the first curved-line region W1. Similarly, the angle θ_{c} is about 0° at the boundary between the straight-line region T and the second curved-line region W2. Therefore, the angle corresponding to the angle θ_{c} in the straight-line region T is about 0°.

The second resonator electrode may also have the same or substantially the same or substantially the same configuration as that of the first resonator electrode in any of the first to fifth modifications. In example embodiments of the present invention, for example, the first resonator electrode may have the configuration of any of the first example embodiment or the first to fifth modifications while the second resonator electrode may also have the same or substantially the same configuration as that of the first example embodiment or the first resonator electrode in any of the first to fifth modifications. An example thereof is illustrated by a sixth modification and a seventh modification of the first example embodiment. As in the first example embodiment, the sixth and seventh modifications also enable reduction or prevention of the acoustic coupling between the acoustic wave resonators and a reduction in the degradation of the electrical characteristics.

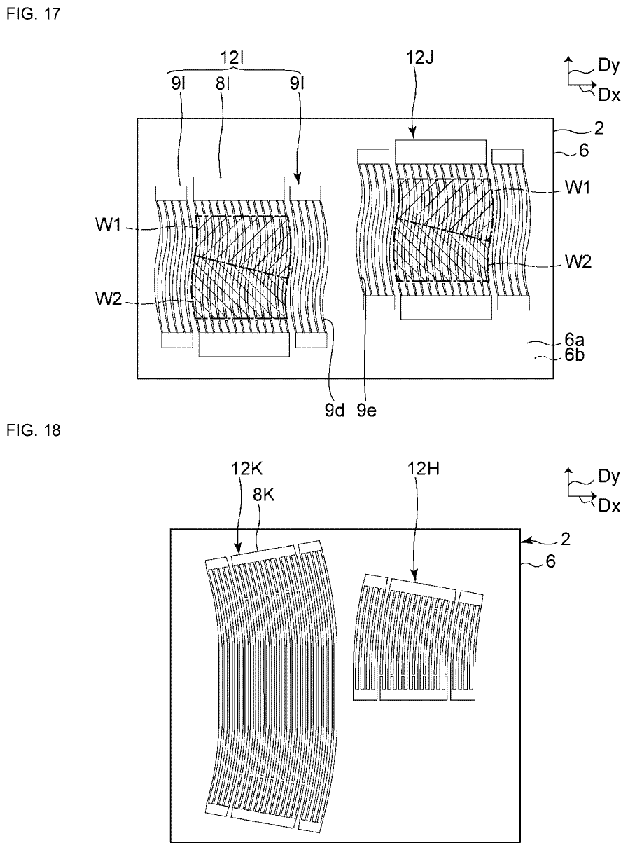

In the sixth modification illustrated in FIG. 17, a first resonator electrode 12I and a second resonator electrode 12J have the same or substantially the same configuration as the first resonator electrode 12I of the fourth modification. The first proximal electrode finger 9d of the first resonator electrode 12I includes two portions in which the outer sides are oriented in different directions from each other. Similarly, the second proximal electrode finger 9e of the second resonator electrode 12J includes two portions in which the outer sides are oriented in different directions from each other.

The portion of the first proximal electrode finger 9d in which the outer side is oriented in the same or substantially the same direction as the outer sides of the electrode fingers in the first curved-line region W1 includes a portion with the shortest distance from the second proximal electrode finger 9e. The second proximal electrode finger 9e is positioned on the outer side of that portion. On the other hand, the portion of the second proximal electrode finger 9e in which the outer side is oriented in the same or substantially the same direction as the outer sides of the electrode fingers in the second curved-line region W2 includes a portion with the shortest distance from the first proximal electrode finger 9d. The first proximal electrode finger 9d is positioned on the outer side of that portion.

In the seventh modification illustrated in FIG. 18, the first resonator electrode 12K has the same or substantially the same configuration as the first resonator electrode 12K in the fifth modification. A second resonator electrode 12H has the same or substantially the same configuration as the first resonator electrode 12G in the third modification.

FIG. 19 is a schematic plan view of an acoustic wave device according to a second example embodiment of the present invention.

The second example embodiment differs from the first example embodiment in that a second resonator electrode 22B is a linear resonator electrode. Specifically, the second resonator electrode 22B includes a second IDT electrode 28B and a pair of second reflectors 29B. Each of a plurality of electrode fingers of the second IDT electrode 28B and a plurality of reflector electrode fingers 29c of each second reflector 29B has a straight shape in plan view. An acoustic wave device 20 of the second example embodiment has the same or substantially the same configuration as the acoustic wave device 10 of the first example embodiment except for the above-described points.

One of the second reflectors 29B of the second resonator electrode 22B includes a second proximal electrode finger 29e. The second proximal electrode finger 29e is positioned on the outer side of a portion of the first proximal electrode finger 9d of the first resonator electrode 12A that has the shortest distance from the second proximal electrode finger 29e.

The first resonator electrode 12A is a curved resonator electrode as in the first example embodiment. In an acoustic wave resonator including the curved resonator electrode, acoustic waves are less likely to leak toward the outer sides of the plurality of electrode fingers. Therefore, acoustic waves excited in the first acoustic wave resonator 1A are less likely to leak towards a second acoustic wave resonator 21B. As a result, it is possible to reduce or prevent the acoustic coupling between the first acoustic wave resonator 1A and the second acoustic wave resonator 21B and thus reduce the degradation of the electrical characteristics of the acoustic wave device.

Thus, in example embodiments of the present invention, it is sufficient that at least one curved resonator electrode is provided.

In the first example embodiment and the modifications thereof described above, the first proximal electrode finger 9d of the first resonator electrode 12A and the second proximal electrode finger 29e of the second resonator electrode 22B face each other and are positioned on their respective outer sides. However, the present invention is not limited to such a configuration. The following description illustrates an example in which the relationship between the outer sides of the first proximal electrode finger 9d and the second proximal electrode finger 29e is different from that described above.

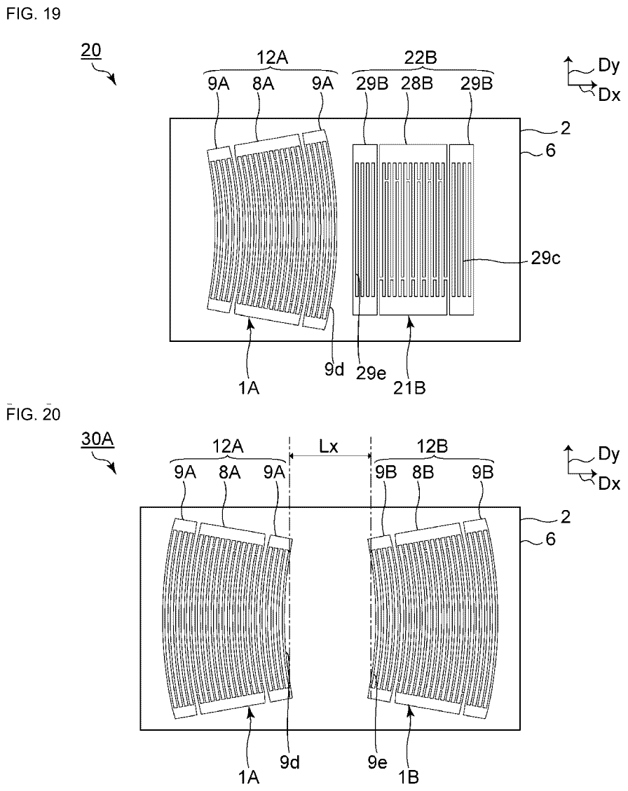

FIG. 20 is a schematic plan view of an acoustic wave device according to a third example embodiment of the present invention.

The third example embodiment differs from the first example embodiment in that the first proximal electrode finger 9d of the first resonator electrode 12A and the second proximal electrode finger 9e of the second resonator electrode 12B face each other and are positioned on their respective inner sides. The third example embodiment differs from the first example embodiment in the distance between the first proximal electrode finger 9d and the second proximal electrode finger 9e. An acoustic wave device 30A of the third example embodiment has the same or substantially the same configuration as the acoustic wave device 10 of the first example embodiment except for the above-described points.

The outer sides of the plurality of electrode fingers in the first resonator electrode 12A correspond to the left in FIG. 20. The inner sides of the plurality of electrode fingers in the first resonator electrode 12A correspond to the right in FIG. 20. On the other hand, the outer sides of the plurality of electrode fingers in the second resonator electrode 12B correspond to the right in FIG. 20. The inner sides of the plurality of electrode fingers in the second resonator electrode 12B correspond to the left in FIG. 20.

The second proximal electrode finger 9e is positioned on the inner side of a portion of the first proximal electrode finger 9d that has the shortest distance from the second proximal electrode finger 9e. The first proximal electrode finger 9d is positioned on the inner side of a portion of the second proximal electrode finger 9e that has the shortest distance from the first proximal electrode finger 9d. The first distance Lx is at least 32λ. The second distance Ly is 0. In this case, it is possible to reduce or prevent the acoustic coupling between the first acoustic wave resonator 1A and the second acoustic wave resonator 1B and thus reduce the degradation of the electrical characteristics of the acoustic wave device 30A. This advantageous effect is described in detail below.

The relationship between the first distance Lx and the maximum ripple magnitude in the return loss was obtained. The first distance Lx was set to, for example, about 2.4λ, about 5λ, about 10λ, about 20λ, about 32λ, about 63λ, about 80λ, and about 100λ.

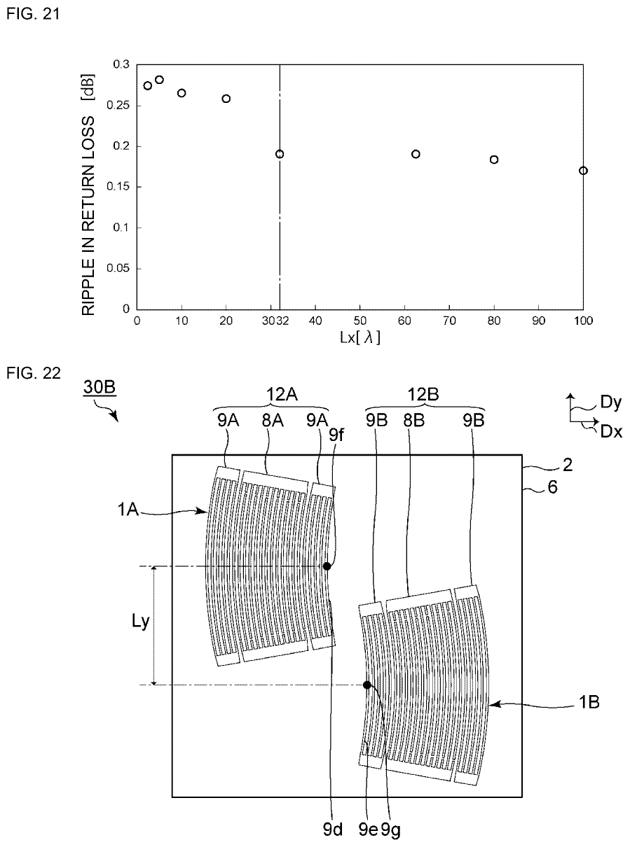

FIG. 21 is a diagram illustrating the relationship between the first distance Lx and the maximum ripple magnitude in the case where the first proximal electrode finger of the first resonator electrode and the second proximal electrode finger of the second resonator electrode face each other and are positioned on their respective inner sides.

FIG. 21 reveals that when the first distance Lx is at least about 32λ, the ripples in the return loss are reduced to below about 0.2 dB. As described above, in an acoustic wave resonator including the curved resonator electrode, like the first resonator electrode 12A and the second resonator electrode 12B illustrated in FIG. 20, acoustic waves tend to leak toward the inner sides of the plurality of electrode fingers. However, in the third example embodiment, the first distance Lx is at least about 32λ, which is sufficiently long. This can reduce the influence of acoustic waves leaking from one acoustic wave resonator on the other acoustic wave resonator. It is therefore possible to reduce or prevent the acoustic coupling between the first acoustic wave resonator 1A and the second acoustic wave resonator 1B.

In the example illustrated in the third example embodiment, the first distance Lx is long. However, even in the case where the second distance Ly is long, as in the third example embodiment, it is possible to reduce or prevent the acoustic coupling between the first acoustic wave resonator and the second acoustic wave resonator and thus reduce the degradation of the electrical characteristics of the acoustic wave device. An example thereof is illustrated by a fourth example embodiment of the present invention.

FIG. 22 is a schematic plan view of an acoustic wave device according to the fourth example embodiment.

The fourth example embodiment differs from the third example embodiment in that, for example, (Ly/La)×100 [%]≥about 12.4 [%] and the first distance Lx is not particularly limited. An acoustic wave device 30B of the fourth example embodiment has the same or substantially the same configuration as the acoustic wave device 30A of the third example embodiment except for the above-described points.

The relationship between the ratio (Ly/La)×100 of the second distance Ly to the proximal intersecting width La and the maximum ripple magnitude in the return loss was obtained. The ratio (Ly/La)×100 was set to, for example, about 0%, about 2.5%, about 7.58, about 12.48, about 24.58, about 49.5%, about 74%, and about 123.5%.

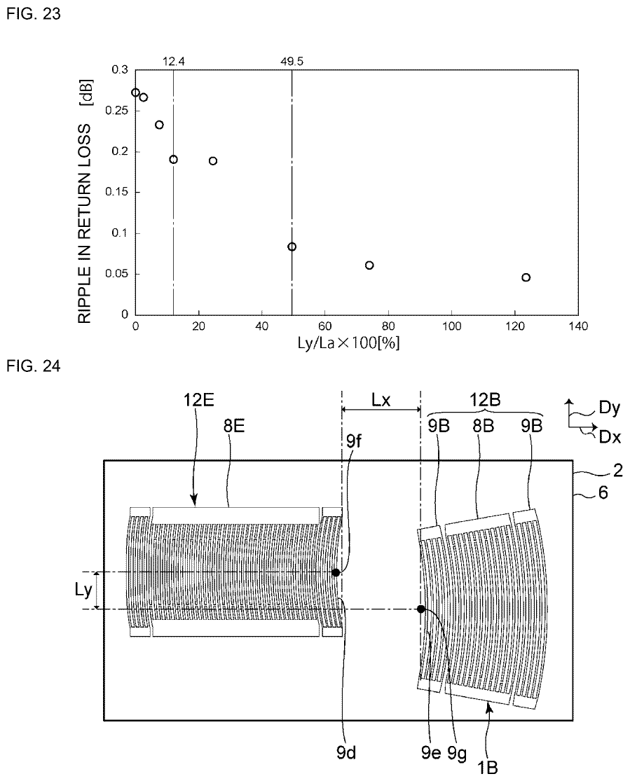

FIG. 23 is a diagram illustrating the relationship between the ratio (Ly/La)×100 and the maximum ripple magnitude in the case where the first proximal electrode finger of the first resonator electrode and the second proximal electrode finger of the second resonator electrode face each other and are positioned on their respective inner sides.

FIG. 23 reveals that ripples in the return loss are reduced to below about 0.2 dB in the case where the ratio (Ly/La)×100 is about 12.4%, compared to the case where the ratio (Ly/La)×100 is about 0%. Furthermore, the higher the ratio (Ly/La)×100 and the longer the second distance Ly, the more the acoustic coupling between the first acoustic wave resonator 1A and the second acoustic wave resonator 1B can be reduced or prevented. When (Ly/La)×100 [%]≥about 12.4 [%] as in the fourth example embodiment, it is possible to reduce or prevent the acoustic coupling between the first acoustic wave resonator 1A and the second acoustic wave resonator 1B and thus reduce the degradation of the electrical characteristics of the acoustic wave device 30B. Preferably, for example, (Ly/La)×100 [%]≥about 49.5 [%]. In this case, ripples in the return loss are reduced to below about 0.1 dB. The acoustic coupling between the first acoustic wave resonator 1A and the second acoustic wave resonator 1B can be further reduced or prevented.

As illustrated in FIG. 22, in the fourth example embodiment, the intersecting region of the first acoustic wave resonator 1A and the intersecting region of the second acoustic wave resonator 1B overlap each other when viewed in the first direction Dx, in which the propagation axis extends. However, the intersecting region of the first acoustic wave resonator 1A and the intersecting region of the second acoustic wave resonator 1B do not need to overlap each other when viewed in the first direction Dx, in which the propagation axis extends.

In the present example embodiment, the first proximal electrode finger 9d of the first resonator electrode 12A and the second proximal electrode finger 9e of the second resonator electrode 12B may face each other and may be positioned on their respective inner sides as in the third and fourth example embodiments. In this case, it is sufficient for the acoustic wave device to include at least one of the configurations in which the first distance Lx is at least about 32λ, or (Ly/La)×100 [%]≥about 12.4 [%], for example.

In the examples illustrated in the third and fourth example embodiments, the first and second resonator electrodes have the same or substantially the same configurations as those of the first example embodiment. In an example embodiment of the present invention, for example, the first resonator electrode may have the configuration of any of the first to fifth modifications of the first example embodiment while the second resonator electrode has the same or substantially the same configuration as that of the first resonator electrode in any of the first to fifth modifications of the first example embodiment. An example thereof is illustrated by a first modification of the fourth example embodiment. As in the fourth example embodiment, the first modification also enables reduction or prevention of the acoustic coupling between the acoustic wave resonators and a reduction in the degradation of the electrical characteristics.

In the first modification illustrated in FIG. 24, the first resonator electrode 12E has the same or substantially the same configuration as that of the second modification of the first example embodiment. The second resonator electrode 12B has the same or substantially the same configuration as that of the third and fourth example embodiments.

In the third and fourth example embodiments, the reference line N in the first acoustic wave resonator and the reference line N in the second acoustic wave resonator both extend parallel or substantially parallel to the first direction Dx, in which the propagation axis extends. However, the present invention is not limited thereto.

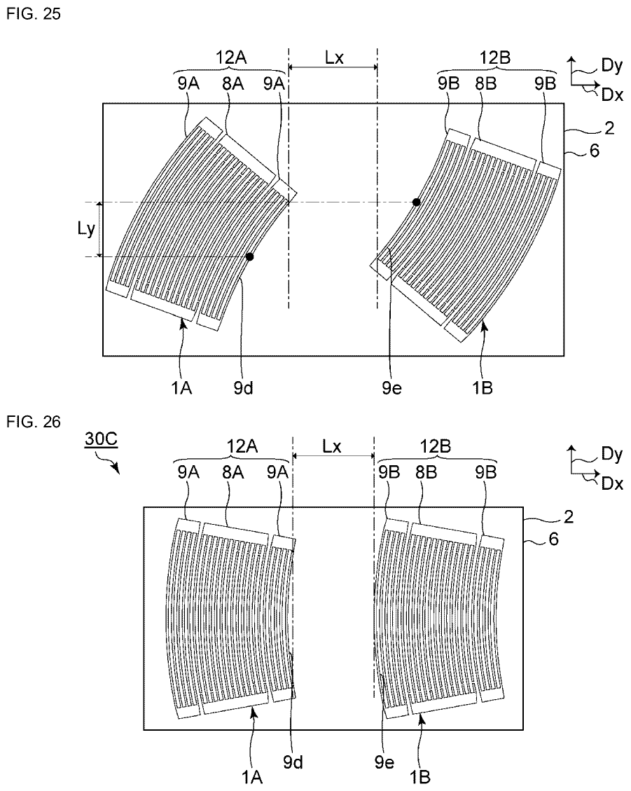

For example, in a second modification of the fourth example embodiment illustrated in FIG. 25, the reference line N in the first acoustic wave resonator 1A and the reference line N in the second acoustic wave resonator 1B both intersect the first direction Dx. In the second modification, for example, the acoustic wave device includes at least one of the configurations in which the first distance Lx is at least about 32λ, or (Ly/La)×100 [%]≥about 12.4 [%]. This can reduce or prevent the acoustic coupling between the first acoustic wave resonator 1A and the second acoustic wave resonator 1B and thus reduce the degradation of the electrical characteristics as in the fourth example embodiment.

When the acoustic wave device includes at least one of the configurations in which the first distance Lx is at least about 32λ, or (Ly/La)×100 [%]≥about 12.4 [%], the outer side of the second resonator electrode is not limited to that described above. In the following description, an example in which the outer side of the second proximal electrode finger is oriented in a different direction from that described above is illustrated by fifth and sixth example embodiments of the present invention. As in the third and fourth example embodiments, the fifth and sixth example embodiments also enable reduction or prevention of the acoustic coupling between the acoustic wave resonators and a reduction in the degradation of the electrical characteristics.

FIG. 26 is a schematic plan view of an acoustic wave device according to a fifth example embodiment of the present invention.

The fifth example embodiment differs from the third example embodiment in that the outer sides of the plurality of electrode fingers in the second resonator electrode 12B correspond to the left in FIG. 26. More specifically, the first proximal electrode finger 9d is positioned on the outer side of a portion of the second proximal electrode finger 9e that has the shortest distance from the first proximal electrode finger 9d. An acoustic wave device 30C of the fifth example embodiment has the same or substantially the same configuration as the acoustic wave device 30A of the third example embodiment except for the above-described points.

In the second acoustic wave resonator 1B, acoustic waves are less likely to leak towards the outer sides of the plurality of electrode fingers. Therefore, acoustic waves excited in the second acoustic wave resonator 1B are less likely to leak towards the first acoustic wave resonator 1A. As a result, it is possible to effectively reduce or prevent the acoustic coupling between the first acoustic wave resonator 1A and the second acoustic wave resonator 1B. In the fifth example embodiment, as in the second example embodiment and the like, of the resonator electrodes, the other resonator electrode is positioned on the outer side of the resonator electrode that is the curved resonator electrode. In this case, for example, the first distance Lx may be less than about 32λ while (Ly/La)×100 [%] may be less than about 12.4 [%]. Even in this case, the acoustic coupling can be reduced or prevented. However, as in the fifth example embodiment, it is preferable that the acoustic wave device includes at least one of the configurations in which the first distance Lx is at least about 32λ, or (Ly/La)×100 [%]≥about 12.4 [%], for example. This can more reliably and effectively reduce or prevent the acoustic coupling and more reliably and effectively reduce the degradation of the electrical characteristics.

At least one of the resonator electrodes may include a plurality of curved-line regions even in the case where the outer sides of the first proximal electrode finger 9d and the second proximal electrode finger 9e are oriented in opposite directions in the portion where the distance between the first proximal electrode finger 9d and the second proximal electrode finger 9e is the shortest.

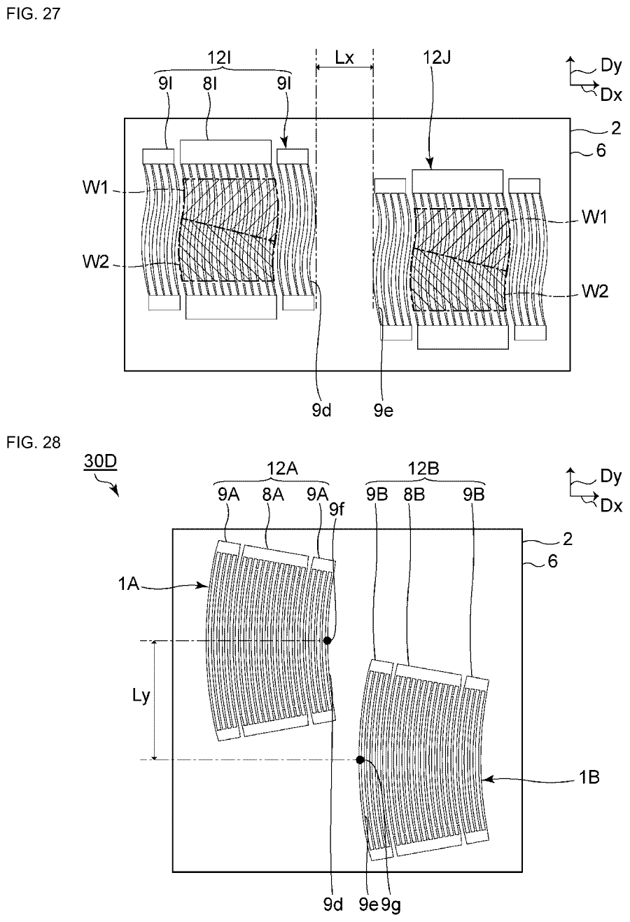

In a modification of the fifth example embodiment illustrated in FIG. 27, for example, the first resonator electrode 12I and a second resonator electrode 12J have the same or substantially the same configurations as the first resonator electrode 12I of the fourth modification of the first example embodiment. The first proximal electrode finger 9d of the first resonator electrode 12I includes two portions in which the outer sides are oriented in different directions from each other. Similarly, the second proximal electrode finger 9e of the second resonator electrode 12J includes two portions in which the outer sides are oriented in different directions from each other.

In this modification, the first proximal electrode finger 9d includes a plurality of portions with the shortest distance from the second proximal electrode finger 9e. The plurality of portions include a first portion and a second portion. In the first portion, the outer side of the first proximal electrode finger 9d corresponds to the right in FIG. 27. In the second portion, the inner side of the first proximal electrode finger 9d corresponds to the right in FIG. 27.

Similarly, the second proximal electrode finger 9e includes a plurality of portions with the shortest distance from the first proximal electrode finger 9d. The plurality of portions include a third portion and a fourth portion. In the third portion, the inner side of the second proximal electrode finger 9e corresponds to the left in FIG. 27. In the fourth portion, the outer side of the second proximal electrode finger 9e corresponds to the left in FIG. 27.

The distance between the first portion of the first proximal electrode finger 9d and the third portion of the second proximal electrode finger 9e is the shortest distance between the first proximal electrode finger 9d and the second proximal electrode finger 9e. The third portion of the second proximal electrode finger 9e is positioned on the outer side of the first portion of the first proximal electrode finger 9d. The first portion of the first proximal electrode finger 9d is positioned on the inner side of the third portion of the second proximal electrode finger 9e.

The distance between the second portion of the first proximal electrode finger 9d and the fourth portion of the second proximal electrode finger 9e is also the shortest distance between the first proximal electrode finger 9d and the second proximal electrode finger 9e. The fourth portion of the second proximal electrode finger 9e is positioned on the inner side of the second portion of the first proximal electrode finger 9d. The second portion of the first proximal electrode finger 9d is positioned on the outer side of the fourth portion of the second proximal electrode finger 9e. As in the fifth example embodiment, this modification also enables reduction or prevention of the acoustic coupling between the acoustic wave resonators and a reduction in the degradation of the electrical characteristics.

FIG. 28 is a schematic plan view of an acoustic wave device according to a sixth example embodiment of the present invention.

The sixth example embodiment differs from the fourth example embodiment in that the outer sides of the plurality of electrode fingers in the second resonator electrode 12B correspond to the left in FIG. 28. More specifically, the first proximal electrode finger 9d is positioned on the outer side of a portion of the second proximal electrode finger 9e that has the shortest distance from the first proximal electrode finger 9d. An acoustic wave device 30D of the sixth example embodiment has the same configuration as the acoustic wave device 30B of the fourth example embodiment except for the above-described point.

In the fifth and sixth example embodiments, the reference line N in the first acoustic wave resonator and the reference line N in the second acoustic wave resonator both extend parallel or substantially parallel to the first direction Dx, in which the propagation axis extends. However, the present invention is not limited thereto.

In the third to sixth example embodiments and the modifications thereof, the second proximal electrode finger is positioned on the inner side of a portion of the first proximal electrode finger that has the shortest distance from the second proximal electrode finger. In this case, for example, it is sufficient for the first proximal electrode finger to be positioned on the outer or inner side of a portion of the second proximal electrode finger that has the shortest distance from the first proximal electrode finger. Furthermore, it is sufficient for the acoustic wave device to include at least one of the configurations in which the first distance Lx is at least about 32λ, or (Ly/La)×100 [%]≥about 12.4 [%], for example.

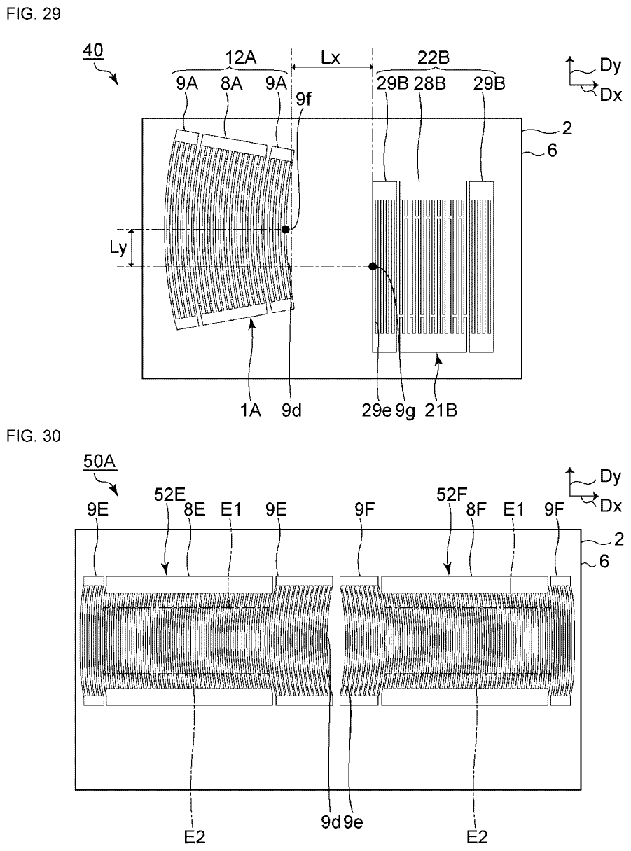

FIG. 29 is a schematic plan view of an acoustic wave device according to a seventh example embodiment of the present invention.

The seventh example embodiment differs from the third example embodiment in that the second resonator electrode 22B is a linear resonator electrode. The second resonator electrode 22B has the same or substantially the same configuration as the second resonator electrode 22B in the second example embodiment. An acoustic wave device 40 of the seventh example embodiment has the same or substantially the same configuration as the acoustic wave device 30A of the third example embodiment except for the above-described point.

The second proximal electrode finger 29e is positioned on the inner side of a portion of the first proximal electrode finger 9d that has the shortest distance from the second proximal electrode finger 29e. In the seventh example embodiment, the acoustic wave device includes at least one of the configurations in which the first distance Lx is at least about 32λ, or (Ly/La)×100 [%]≥about 12.4 [%], for example. This can reduce the influence of acoustic waves leaking from the first acoustic wave resonator 1A on the second acoustic wave resonator 21B. It is therefore possible to reduce or prevent the acoustic coupling between the first acoustic wave resonator 1A and the second acoustic wave resonator 21B and thus reduce the degradation of the electrical characteristics of the acoustic wave device 40.

In the third to seventh example embodiments described above, the second proximal electrode finger is positioned on the inner side of a portion of the first proximal electrode finger that has the shortest distance from the second proximal electrode finger. It is sufficient for the first proximal electrode finger to be positioned on the outer or inner side of a portion of the second proximal electrode finger that has the shortest distance from the first proximal electrode finger. In this case, an acoustic wave device according to an example embodiment of the present invention does not need to include the configurations in which the first distance Lx is at least about 32λ, and (Ly/La)×100 [%]≥about 12.4 [%]. An example thereof is illustrated below.

FIG. 30 is a schematic plan view of an acoustic wave device according to an eighth example embodiment of the present invention.

The eighth example embodiment differs from the third example embodiment in that in the pair of first reflectors 9E, the plurality of reflector electrode fingers differ in number. The eighth example embodiment also differs from the third example embodiment in that in the pair of second reflectors 9F, the plurality of reflector electrode fingers differ in number. The eighth example embodiment also differs from the third example embodiment in that the first envelope E1, the second envelope E2, and the reference line N extend parallel or substantially parallel to each other in each of a first resonator electrode 52E and a second resonator electrode 52F. Furthermore, the eighth example embodiment also differs from the third example embodiment in that the first distance Lx is not particularly limited and the ratio (Ly/La)×100 of the second distance Ly to the proximal intersecting width La is not particularly limited. An acoustic wave device 50A of the eighth example embodiment has the same or substantially the same configuration as the acoustic wave device 30A of the third example embodiment except for the above-described points.

Specifically, between the pair of first reflectors 9E in the first resonator electrode 52E, the number of the plurality of reflector electrode fingers of the first reflector 9E positioned closer to the second IDT electrode 8F of the second resonator electrode 52F is greater than that of the other first reflector 9E. This can reduce the leakage of acoustic waves excited in the first acoustic wave resonator toward the second acoustic wave resonator. It is therefore possible to reduce or prevent the acoustic coupling between the first acoustic wave resonator and the second acoustic wave resonator and thus reduce the degradation of the electrical characteristics of the acoustic wave device 50A.

Furthermore, between the pair of second reflectors 9F in the second resonator electrode 52F, the number of the plurality of reflector electrode fingers of the second reflector 9F positioned closer to the first IDT electrode 8E of resonator electrode 52E is greater than that of the other second reflector 9F. This can reduce the leakage of acoustic waves excited in the second acoustic wave resonator toward the first acoustic wave resonator. It is therefore possible to effectively reduce or prevent the acoustic coupling between the first acoustic wave resonator and the second acoustic wave resonator and thus effectively reduce the degradation of the electrical characteristics of the acoustic wave device 50A. The relationship between the number of the pluralities of reflector electrode fingers of the pair of second reflectors 9F in the second resonator electrode 52F is not limited to that described above.

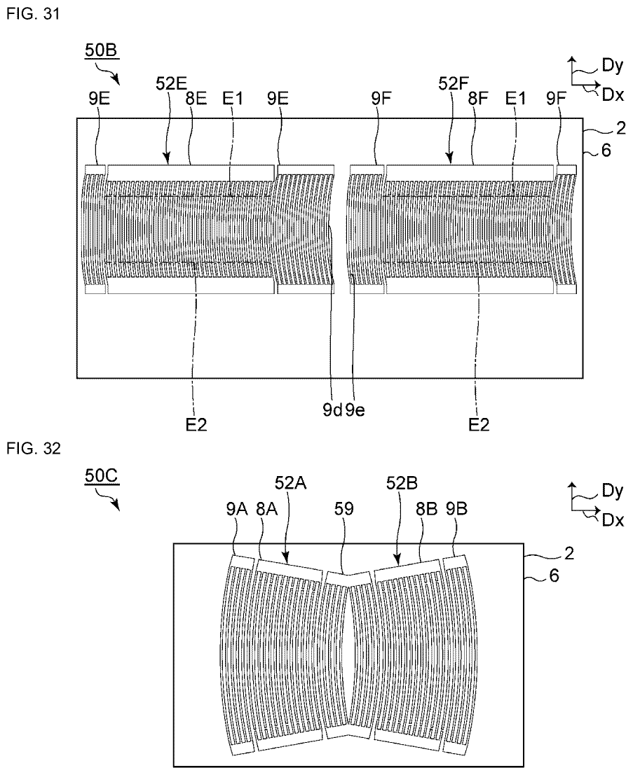

FIG. 31 is a schematic plan view of an acoustic wave device according to a ninth example embodiment of the present invention.

The ninth example embodiment differs from the eighth example embodiment in that the outer sides of the plurality of electrode fingers of the second resonator electrode 52F correspond to the left in FIG. 31. An acoustic wave device 50B of the ninth example embodiment has the same or substantially the same configuration as the acoustic wave device 50A of the eighth example embodiment except for the above-described point.

As in the eighth example embodiment, the ninth example embodiment also enables reduction or prevention of the acoustic coupling between the first acoustic wave resonator and the second acoustic wave resonator and a reduction in the degradation of the electrical characteristics of the acoustic wave device 50B.

FIG. 32 is a schematic plan view of an acoustic wave device according to a tenth example embodiment of the present invention.

The tenth example embodiment differs from the eighth example embodiment in that one of the first reflectors of the first resonator electrode 52A and one of the second reflectors of the second resonator electrode 52B are integrated with each other. Specifically, a reflector 59 is provided between the first IDT electrode 8A and the second IDT electrode 8B. Furthermore, the tenth example embodiment differs from the eighth example embodiment in that the IDT electrode and the one reflector of each resonator electrode have the same or substantially the same configurations as those of the first example embodiment. An acoustic wave device 50C of the tenth example embodiment has the same or substantially the same configuration as the acoustic wave device 50A of the eighth example embodiment.

In the first resonator electrode 52A, the reflector 59 is positioned closer to the second IDT electrode 8B of the second resonator electrode 52B than the first reflector 9A. The number of the plurality of reflector electrode fingers of the reflector 59 is greater than that of the first reflector 9A. This can reduce the leakage of acoustic waves excited in the first IDT electrode 8A toward the second IDT electrode 8B. It is therefore possible to reduce or prevent the acoustic coupling between the first acoustic wave resonator and the second acoustic wave resonator and thus reduce the degradation of the electrical characteristics of the acoustic wave device 50C.

In the second resonator electrode 52B, the reflector 59 is positioned closer to the first IDT electrode 8A than the second reflector 9B. The number of the plurality of reflector electrode fingers of the reflector 59 is greater than that of the second reflector 9B. This can reduce the leakage of acoustic waves excited in the second IDT electrode 8B toward the first IDT electrode 8A. It is therefore possible to effectively reduce or prevent the acoustic coupling between the first acoustic wave resonator and the second acoustic wave resonator and effectively reduce the degradation of the electrical characteristics of the acoustic wave device 50C. The relationship between the number of the plurality of reflector electrode fingers of the second reflector 9B and the number of the plurality of reflector electrode fingers of the reflector 59 is not limited to that described above.

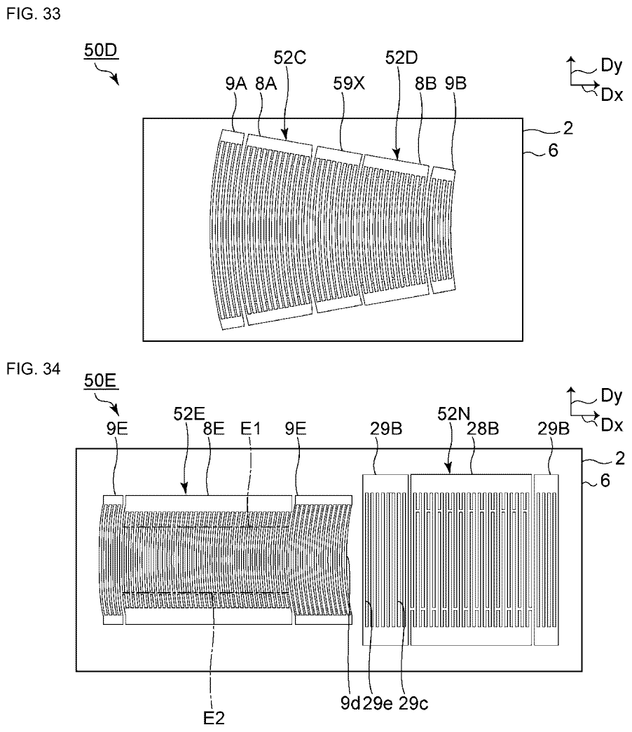

FIG. 33 is a schematic plan view of an acoustic wave device according to an eleventh example embodiment of the present invention.

The eleventh example embodiment differs from the tenth example embodiment in that the outer sides of the plurality of electrode fingers of a second resonator electrode 52D correspond to the left in FIG. 33. The eleventh example embodiment also differs from the tenth example embodiment in that the intersecting width of the second IDT electrode 8B is smaller than that of the first IDT electrode 8A. Furthermore, the eleventh example embodiment differs from the tenth example embodiment in that the dimension of the second reflector 9B of the second resonator electrode 52D in the second direction Dy is smaller than that of the first reflector 9A of a first resonator electrode 52C in the second direction Dy. An acoustic wave device 50D of the eleventh example embodiment has the same or substantially the same configuration as the acoustic wave device 50C of the tenth example embodiment except for the above-described points.

According to the eleventh example embodiment, as in the tenth example embodiment, one of the first reflectors of the first resonator electrode 52C and one of the second reflectors of the second resonator electrode 52D are integrated with each other. Specifically, a reflector 59X is provided between the first IDT electrode 8A and the second IDT electrode 8B. Furthermore, the number of the plurality of reflector electrode fingers of the reflector 59X is greater than that of the first reflector 9A. The number of the plurality of reflector electrode fingers of the reflector 59X is greater than that of the second reflector 9B. This can reduce or prevent the acoustic coupling between the first acoustic wave resonator and the second acoustic wave resonator and thus reduce the degradation of the electrical characteristics of the acoustic wave device 50D. The relationship between the number of the plurality of reflector electrode fingers of the second reflector 9B and the number of the plurality of reflector electrode fingers of the reflector 59X is not limited to that described above.

FIG. 34 is a schematic plan view of an acoustic wave device according to a twelfth example embodiment of the present invention.

The twelfth example embodiment differs from the ninth example embodiment in that a second resonator electrode 52N is the linear resonator electrode. An acoustic wave device 50E of the twelfth example embodiment has the same or substantially the same configuration as the acoustic wave device 50B of the ninth example embodiment except for the above-described point.

As in the ninth example embodiment, the twelfth example embodiment also enables a reduction of the leakage of acoustic waves excited in the first acoustic wave resonator toward the second acoustic wave resonator. It is therefore possible to reduce or prevent the acoustic coupling between the first acoustic wave resonator and the second acoustic wave resonator and thus reduce the degradation of the electrical characteristics of the acoustic wave device 50E.

Furthermore, among the pair of second reflectors 29B in the second resonator electrode 52N, the number of the plurality of reflector electrode fingers 29c of the second reflector 29B positioned closer to the first IDT electrode 8E of the first resonator electrode 52E is greater than that of the other second reflector 29B. This can reduce the leakage of acoustic waves excited in the second acoustic wave resonator toward the first acoustic wave resonator. It is therefore possible to effectively reduce or prevent the acoustic coupling between the first acoustic wave resonator and the second acoustic wave resonator and effectively reduce the degradation of the electrical characteristics of the acoustic wave device 50E. In the second resonator electrode 52N, the relationship in the number of the plurality of reflector electrode fingers 29c between the pair of second reflectors 29B is not limited to that described above.

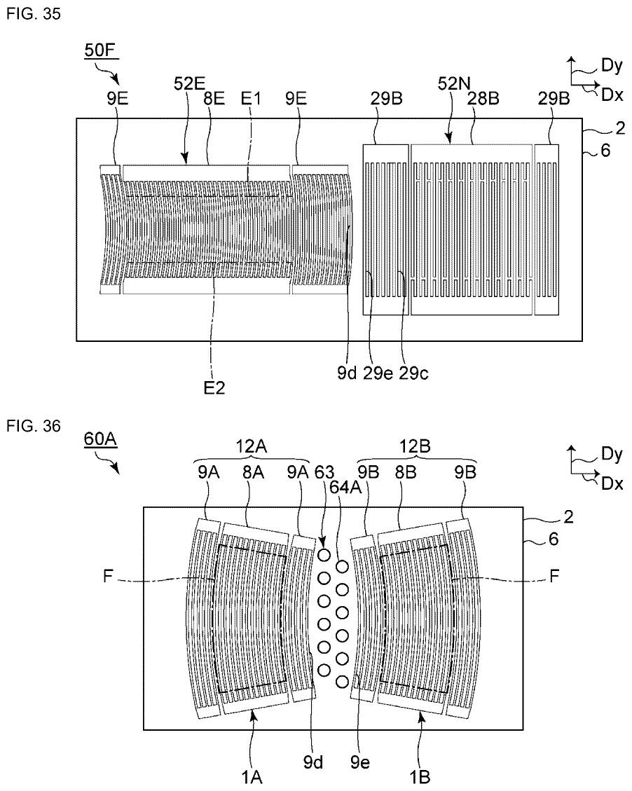

FIG. 35 is a schematic plan view of an acoustic wave device according to a thirteenth example embodiment of the present invention.

The thirteenth example embodiment differs from the twelfth example embodiment in that the outer sides of the plurality of electrode fingers of the first resonator electrode 52E correspond to the right in FIG. 35. An acoustic wave device 50F of the thirteenth example embodiment has the same or substantially the same configuration as the acoustic wave device 50E of the twelfth example embodiment except for the above-described point.

As in the twelfth example embodiment, the thirteenth example embodiment also enables a reduction of the leakage of acoustic waves excited in the first acoustic wave resonator toward the second acoustic wave resonator and a reduction of the leakage of acoustic waves excited in the second acoustic wave resonator toward the first acoustic wave resonator. It is therefore possible to effectively reduce or prevent the acoustic coupling between the first acoustic wave resonator and the second acoustic wave resonator and effectively reduce the degradation of the electrical characteristics of the acoustic wave device 50F.

The first resonator electrode 52E is the curved resonator electrode. In the first acoustic wave resonator, acoustic waves are less likely to leak toward the outer sides of the plurality of electrode fingers. Therefore, acoustic waves excited in the first acoustic wave resonator are accordingly less likely to leak toward the second acoustic wave resonator. As a result, it is possible to further reduce or prevent the acoustic coupling between the first acoustic wave resonator and the second acoustic wave resonator and thus further reduce the degradation of the electrical characteristics of the acoustic wave device 50F.

FIG. 36 is a schematic plan view of an acoustic wave device according to a fourteenth example embodiment of the present invention.

The fourteenth example embodiment differs from the third example embodiment in that an acoustic scattering pattern 63 is provided between the first resonator electrode 12A and the second resonator electrode 12B on the piezoelectric substrate 2. The fourteenth example embodiment also differs from the third example embodiment in that the first distance Lx is not particularly limited and the ratio (Ly/La)×100 of the second distance Ly to the proximal intersecting width La is not particularly limited. An acoustic wave device 60A of the fourteenth example embodiment has the same or substantially the same configuration as the acoustic wave device 30A of the third example embodiment except for the above-described points.

The acoustic scattering pattern 63 includes a plurality of reflectors 64A. Each reflector 64A reflects an acoustic wave having propagated in one direction into a different direction. The plurality of reflectors 64A individually reflect acoustic waves to scatter the acoustic waves. In the fourteenth example embodiment, the plurality of reflectors 64A are circular in plan view. The shapes of the reflectors 64A are not limited to those described above.

Among all of the reflectors 64A, two or more reflectors 64A are provided in a single row so as to be aligned in the direction perpendicular or substantially perpendicular to the direction in which the plurality of electrode fingers of the first resonator electrode 12A are arranged. The remaining reflectors 64A are provided in another single row in a similar manner. That is, the plurality of reflectors 64A are arranged in two rows: one positioned closer to the first resonator electrode 12A and the other positioned closer to the second resonator electrode 12B. The reflectors 64A positioned closer to the first resonator electrode 12A and the reflectors 64A positioned closer to the second resonator electrode 12B are alternately arranged in the direction perpendicular or substantially perpendicular to the direction in which the plurality of electrode fingers of the first resonator electrode 12A are arranged.

The plurality of reflectors 64A are provided in a region that overlaps the intersecting region F of the first resonator electrode 12A when viewed in the first direction Dx. More specifically, the plurality of reflectors 64A are arranged such that when viewed in the first direction Dx, no area is left in this region without any reflector 64A.

Similarly, the plurality of reflectors 64A are provided in a region that overlaps the intersecting region F of the second resonator electrode 12B when viewed in the first direction Dx. More specifically, the plurality of reflectors 64A are arranged such that when viewed in the first direction Dx, no area is left in this region without any reflector 64A. The arrangement of the plurality of reflectors 64A corresponds to the arrangement in which when viewed in the first direction Dx, the reflectors 64A provided closer to the first resonator electrode 12A are in contact with the respective reflectors 64A provided closer to the second resonator electrode 12B. That is, when viewed in the first direction Dx, any two adjacent reflectors 64A are partially aligned at the same or substantially the same position in the second direction Dy.

In an acoustic wave resonator including the curved resonator electrode, such as the first resonator electrode 12A and the second resonator electrode 12B, acoustic waves tend to leak toward the inner sides of the plurality of electrode fingers. However, in the fourteenth example embodiment, the acoustic scattering pattern 63 is provided between the first resonator electrode 12A and the second resonator electrode 12B. Acoustic waves leaking from one of the acoustic wave resonators can be scattered by the acoustic scattering pattern 63. This can reduce the influence of the acoustic waves leaking from one of the acoustic wave resonators on the other acoustic wave resonator. It is therefore possible to reduce or prevent the acoustic coupling between the first acoustic wave resonator 1A and the second acoustic wave resonator 1B and thus reduce the degradation of the electrical characteristics.

When viewed in the first direction Dx, the reflectors 64A provided closer to the first resonator electrode 12A and the reflectors 64A provided closer to the second resonator electrode 12B are not necessarily in contact with each other. However, when viewed in the first direction Dx, it is preferable that the reflectors 64A provided closer to the first resonator electrode 12A and the reflectors 64A provided closer to the second resonator electrode 12B are in contact with each other. This enables effective scattering of acoustic waves leaking from one of the acoustic wave resonators by the acoustic scattering pattern 63.

In the fourteenth example embodiment, all of the reflectors 64A have the same or substantially the same shape and size. However, the plurality of reflectors 64A may include reflectors 64A with different shapes and sizes. The plurality of reflectors 64A do not need to be arranged in two rows. For example, the plurality of reflectors 64A may be arranged in a single row, three rows, or the like, and sections with different numbers of rows, such as a single row and two rows, may be mixed.

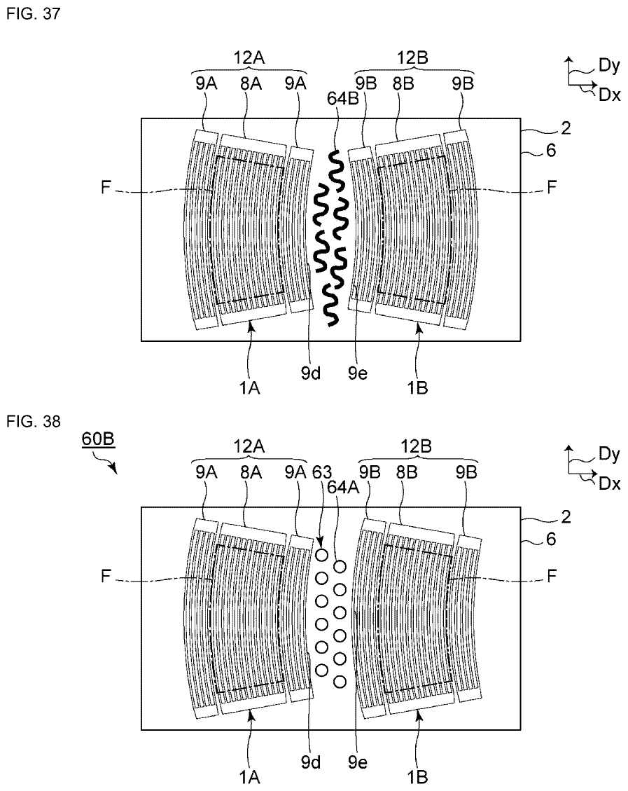

For example, in a modification of the fourteenth example embodiment illustrated in FIG. 37, each of a plurality of reflectors 64B has a wavy shape in plan view. Specifically, each reflector 64B has the shape of two or more connected curves. The arrangement of the plurality of reflectors 64B includes a mixture of sections with a single row and two rows. As in the fourteenth example embodiment, this modification also enables reduction or prevention of the acoustic coupling between the first acoustic wave resonator 1A and the second acoustic wave resonator 1B and a reduction in the degradation of the electrical characteristics.

In the following description, other examples provided with an acoustic reflection pattern are illustrated by fifteenth to seventeenth example embodiments. As in the fourteenth example embodiment, the fifteenth to seventeenth example embodiments also enable reduction or prevention of the acoustic coupling between the first and second acoustic wave resonators and a reduction in the degradation of the electrical characteristics.

FIG. 38 is a schematic plan view of an acoustic wave device according to a fifteenth example embodiment of the present invention.

The fifteenth example embodiment differs from the fourteenth example embodiment in that the outer sides of the plurality of electrode fingers of the second resonator electrode 12B correspond to the left in FIG. 38. More specifically, the first proximal electrode finger 9d is positioned on the outer side of a portion of the second proximal electrode finger 9e that has the shortest distance from the first proximal electrode finger 9d. An acoustic wave device 60B of the fifteenth example embodiment has the same or substantially the same configuration as the acoustic wave device 60A of the fourteenth example embodiment except for the above-described point.

In the fifteenth example embodiment, acoustic waves excited in the second acoustic wave resonator 1B are less likely to leak toward the first acoustic wave resonator 1A. It is therefore possible to effectively reduce or prevent the acoustic coupling between the first acoustic wave resonator 1A and the second acoustic wave resonator 1B.

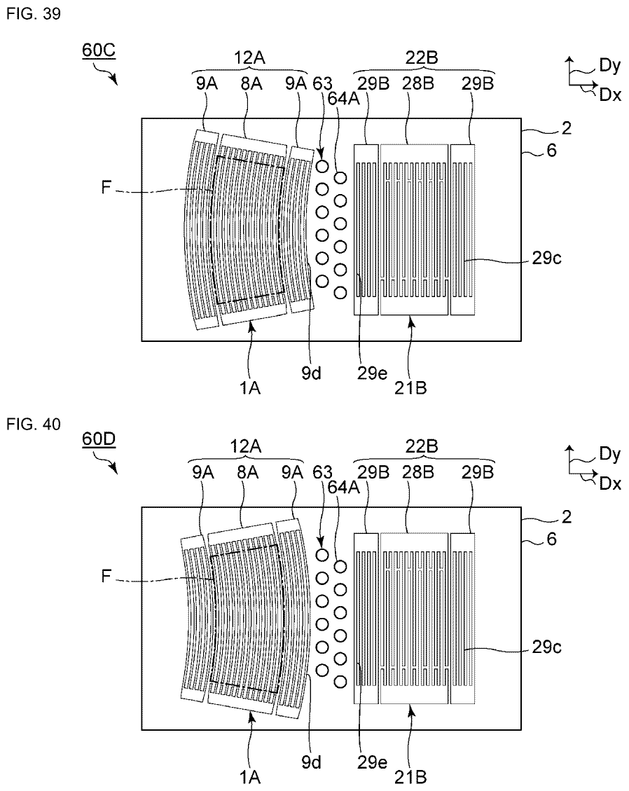

FIG. 39 is a schematic plan view of an acoustic wave device according to a sixteenth example embodiment of the present invention.

The sixteenth example embodiment differs from the fifteenth example embodiment in that the second resonator electrode 22B is the linear resonator electrode. The second resonator electrode 22B has the same or substantially the same configuration as the second resonator electrode 22B of the second example embodiment. An acoustic wave device 60C of the sixteenth example embodiment has the same or substantially the same configuration as the acoustic wave device 60B of the fifteenth example embodiment except for the above-described point.

FIG. 40 is a schematic plan view of an acoustic wave device according to a seventeenth example embodiment example embodiment.

The seventeenth example embodiment differs from the sixteenth example embodiment in that the outer sides of the plurality of electrode fingers of the first resonator electrode 12A correspond to the right in FIG. 40. More specifically, the second proximal electrode finger 29e is positioned on the outer side of a portion of the first proximal electrode finger 9d that has the shortest distance from the second proximal electrode finger 29e. An acoustic wave device 60D of the seventeenth example embodiment has the same or substantially the same configuration as the acoustic wave device 60C of the sixteenth example embodiment except for the above-described point.

In the seventeenth example embodiment, acoustic waves excited in the first acoustic wave resonator 1A are less likely to leak toward the second acoustic wave resonator 21B. It is therefore possible to effectively reduce or prevent the acoustic coupling between the first acoustic wave resonator 1A and the second acoustic wave resonator 21B.

In the case where the intersecting regions of two acoustic wave resonators overlap each other when viewed in the first direction Dx, in which the propagation axis extends, the two acoustic wave resonators tend to be acoustically coupled in structures in the related art. In the first to seventeenth example embodiments, the intersecting region of the first acoustic wave resonator and the intersecting region of the second acoustic wave resonator overlap each other when viewed in the first direction Dx. Despite this, the acoustic coupling between the first and second acoustic wave resonators can be reduced or prevented as described above in the first to seventeenth example embodiments. Thus, it is possible to reduce or prevent the acoustic coupling between the acoustic wave resonators and improve the layout flexibility.

Acoustic wave devices according to example embodiments of the present invention may include three or more acoustic wave resonators. In this case, the acoustic wave device may include more than one of the configurations in the first through seventeenth example embodiments. For example, in three acoustic wave resonators arranged in the first direction Dx, the center acoustic wave resonator and one of the acoustic wave resonators adjacent to the center acoustic wave resonator may have the configuration of the first example embodiment illustrated in FIG. 1. In this case, the center acoustic wave resonator and the other adjacent acoustic wave resonator may have the configuration of the fifth example embodiment illustrated in FIG. 26.

The lamination structure of the piezoelectric substrate is not limited to the configuration illustrated in FIG. 2. An eighteenth example embodiment illustrates an example in which the acoustic wave device includes a piezoelectric substrate different from that of the first example embodiment.

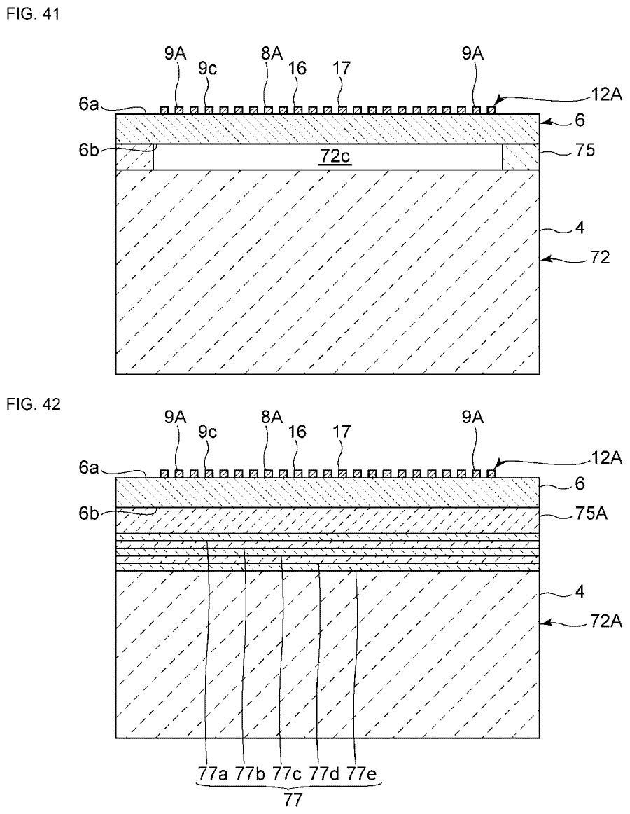

FIG. 41 is a schematic elevational cross-sectional view of an acoustic wave device according to the eighteenth example embodiment of the present invention.

The eighteenth example embodiment differs from the first example embodiment in the lamination structure of a piezoelectric substrate 72. FIG. 41 illustrates the first resonator electrode 12A. On the piezoelectric substrate 72, the second resonator electrode 12B, which is the same or substantially the same as that of the first example embodiment, is also provided (not illustrated). The acoustic wave device of the eighteenth example embodiment has the same or substantially the same configuration as the acoustic wave device 10 of the first example embodiment except for the above-described point.

The piezoelectric substrate 72 includes the support substrate 4, an intermediate layer 75, and the piezoelectric layer 6. The intermediate layer 75 is provided on the support substrate 4. The piezoelectric layer 6 is provided on the intermediate layer 75. The intermediate layer 75 has a frame shape in the eighteenth example embodiment. That is, the intermediate layer 75 includes a through-hole. The support substrate 4 closes one end of the through-hole of the intermediate layer 75. The piezoelectric layer 6 closes the other end of the through-hole of the intermediate layer 75. A hollow portion 72c is thus provided in the piezoelectric substrate 72. A portion of the piezoelectric layer 6 and a portion of the support substrate 4 face each other across the hollow portion 72c.

In the eighteenth example embodiment, acoustic waves can be reflected toward the piezoelectric layer 6. Therefore, acoustic waves can be effectively confined on the piezoelectric layer 6 side. In addition, as in the first example embodiment, the acoustic coupling between the acoustic wave resonators can be reduced or prevented, and the degradation of the electrical characteristics can be reduced.

The following description a first illustrates modification and a second modification of the eighteenth example embodiment, which differ from the eighteenth example embodiment only in the lamination structure of the piezoelectric substrate. As in the eighteenth example embodiment, the first and second modifications also enable reduction or prevention of the acoustic coupling between the acoustic wave resonators and a reduction in the degradation of the electrical characteristics. Furthermore, the first and second modifications enable effective confinement of acoustic waves to the piezoelectric layer 6 side.

In the first modification illustrated in FIG. 42, a piezoelectric substrate 72A includes the support substrate 4, an acoustic reflective film 77, an intermediate layer 75A, and the piezoelectric layer 6. The acoustic reflective film 77 is provided on the support substrate 4. The intermediate layer 75A is provided on the acoustic reflective film 77. The piezoelectric layer 6 is provided on the intermediate layer 75A. The intermediate layer 75A is the low-velocity film.

The acoustic reflective film 77 is a laminate of two or more acoustic impedance layers. Specifically, the acoustic reflective film 77 includes a plurality of low acoustic impedance layers and a plurality of high acoustic impedance layers. The high acoustic impedance layers are layers with relatively high acoustic impedance. The plurality of high acoustic impedance layers of the acoustic reflective film 77 are, more specifically, a high acoustic impedance layer 77a, a high acoustic impedance layer 77c, and a high acoustic impedance layer 77e. The low acoustic impedance layers are layers with relatively low acoustic impedance. The plurality of low acoustic impedance layers of the acoustic reflective film 77 are, more specifically, a low acoustic impedance layer 77b and a low acoustic impedance layer 77d. The low acoustic impedance layers and the high acoustic impedance layers are alternately laminated on top of each other. The high acoustic impedance layer 77a is the layer that is the closest to the piezoelectric layer 6 in the acoustic reflective film 77.

The acoustic reflective film 77 includes two low acoustic impedance layers and three high acoustic impedance layers, for example. However, it is sufficient for the acoustic reflective film 77 to include at least one low acoustic impedance layer and at least one high acoustic impedance layer.

Examples of the material of the low acoustic impedance layers include silicon oxide or aluminum. Examples of the material of the high acoustic impedance layers include metal such as platinum or tungsten and dielectrics such as aluminum nitride or silicon nitride. The material of the intermediate layer 75A may be the same as that of the low acoustic impedance layers.

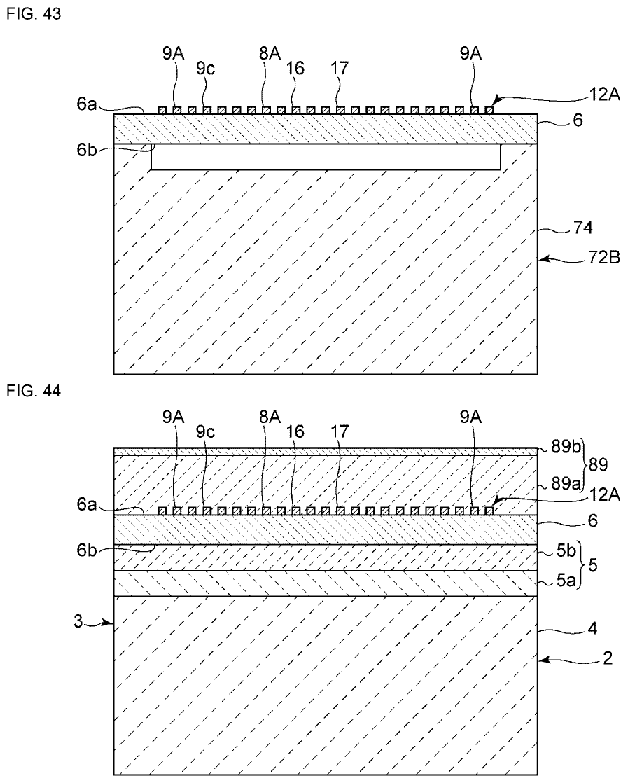

In the second modification illustrated in FIG. 43, a piezoelectric substrate 72B includes a support substrate 74 and the piezoelectric layer 6. The piezoelectric layer 6 is provided directly on the support substrate 74. More specifically, the support substrate 74 includes a recess portion. The piezoelectric layer 6 is provided on the support substrate 74 to close the recess portion. The piezoelectric substrate 72B thus includes a hollow portion. The hollow portion overlaps at least a portion of the first IDT electrode 8A in plan view.

FIG. 44 is a schematic elevational cross-sectional view of an acoustic wave device according to a nineteenth example embodiment of the present invention.

The nineteenth example embodiment differs from the first example embodiment in that the first resonator electrode 12A is embedded in a protection film 89. The nineteenth example embodiment also differs from the first example embodiment in that the second resonator electrode 12B illustrated in FIG. 1 is embedded in the protection film 89 (not illustrated). The acoustic wave device of the nineteenth example embodiment has the same or substantially the same configuration as the acoustic wave device 10 of the first example embodiment except for the above-described points.

Specifically, the protection film 89 is provided on the piezoelectric layer 6 so as to cover the first resonator electrode 12A. The protection film 89 is thicker than the first resonator electrode 12A. The first resonator electrode 12A is embedded in the protection film 89. The first resonator electrode 12A is therefore less likely to be damaged. The second resonator electrode 12B is also less likely to be damaged.

The protection film 89 includes a first protection layer 89a and a second protection layer 89b. The first resonator electrode 12A and the second resonator electrode 12B are embedded in the first protection layer 89a. The second protection layer 89b is provided on the first protection layer 89a. The protection film 89 therefore provides multiple advantageous effects. Specifically, the first protection layer 89a is made of, for example, silicon oxide in the nineteenth example embodiment. This can reduce the absolute value of the temperature coefficient of frequency (TCF) of the acoustic wave device, thus improving the temperature characteristics of the acoustic wave device. The second protection layer 89b is made of, for example, silicon nitride. This can improve the resistance to humidity.

In addition, the first resonator electrode 12A and the second resonator electrode 12B of the nineteenth example embodiment are configured in the same or substantially the same manner as those of the first example embodiment. It is therefore possible to reduce or prevent the acoustic coupling between the acoustic wave resonators and thus reduce the degradation of the electrical characteristics.

The materials of the first protection layer 89a and the second protection layer 89b are not limited to those described above. The protection film 89 may include a single layer or a laminate of three layers or more.

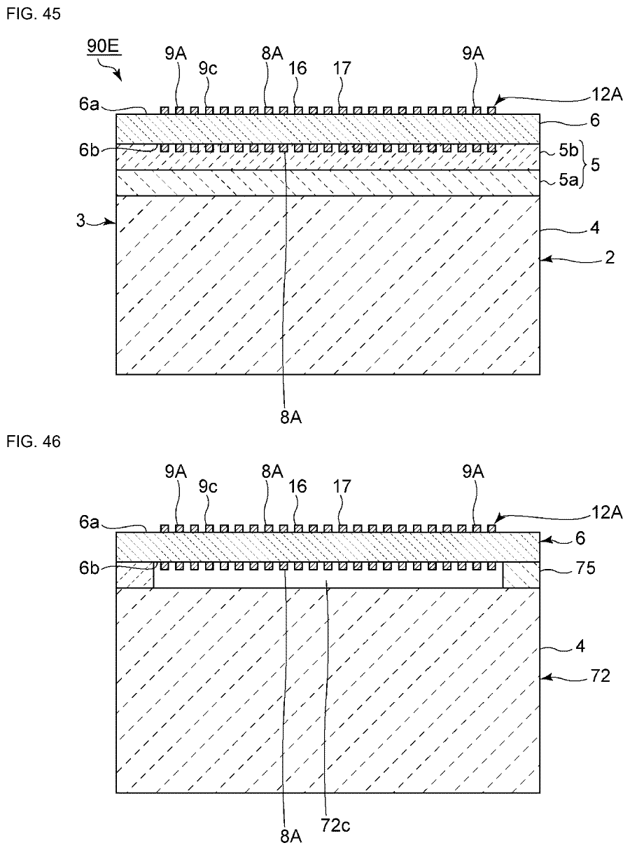

FIG. 45 is a schematic elevational cross-sectional view of an acoustic wave device according to a twentieth example embodiment of the present invention.

The twentieth example embodiment differs from the first example embodiment in that the first resonator electrode 12A is provided on each of the first main surface 6a and the second main surface 6b of the piezoelectric layer 6. The twentieth example embodiment also differs from the first example embodiment in that the second resonator electrode 12B illustrated in FIG. 1 is provided on each of the first main surface 6a and the second main surface 6b of the piezoelectric layer 6 (not illustrated). The first resonator electrode 12A and the second resonator electrode 12B provided on the second main surface 6b are embedded in the second layer 5b of the intermediate layer 5. An acoustic wave device 90E of the twentieth example embodiment has the same or substantially the same configuration as the acoustic wave device 10 of the first example embodiment except for the above points.

The first resonator electrode 12A provided on the first main surface 6a of the piezoelectric layer 6 and the first resonator electrode 12A provided on the second main surface 6b face each other across the piezoelectric layer 6. The second resonator electrode 12B provided on the first main surface 6a of the piezoelectric layer 6 and the second resonator electrode 12B provided on the second main surface 6b face each other across the piezoelectric layer 6.

In the acoustic wave device 90E of the twentieth example embodiment, the first resonator electrode 12A and the second resonator electrode 12B on the first main surface 6a have the same or substantially the same configurations as those of the first example embodiment. The first resonator electrode 12A and the second resonator electrode 12B on the second main surface 6b also have the same or substantially the same configurations as those of the first example embodiment. It is therefore possible to reduce or prevent the acoustic coupling between the acoustic wave resonators and thus reduce the degradation of the electrical characteristics.

The first resonator electrodes 12A provided on the first main surface 6a and the second main surface 6b of the piezoelectric layer 6 may differ from each other, for example, in design parameters. The second resonator electrodes 12B provided on the first main surface 6a and the second main surface 6b may differ from each other, for example, in design parameters.

The following description illustrates first to third modifications of the twentieth example embodiment, which differ from the twentieth example embodiment only in at least one of the configuration of the electrodes provided on the second main surface of the piezoelectric layer or the lamination structure of the piezoelectric substrate. As in the twentieth example embodiment, the first to third modifications also enable reduction or prevention of the acoustic coupling between the acoustic wave resonators and a reduction of the degradation of the electrical characteristics.

In the first modification illustrated in FIG. 46, the piezoelectric substrate 72 is configured in the same or substantially the same manner as in the eighteenth example embodiment. Specifically, the piezoelectric substrate 72 includes the support substrate 4, the intermediate layer 75, and the piezoelectric layer 6. The first resonator electrode 12A provided on the second main surface 6b of the piezoelectric layer 6 is positioned within the hollow portion 72c. The second resonator electrode 12B provided on the second main surface 6b is also positioned within the hollow portion 72c (not illustrated).

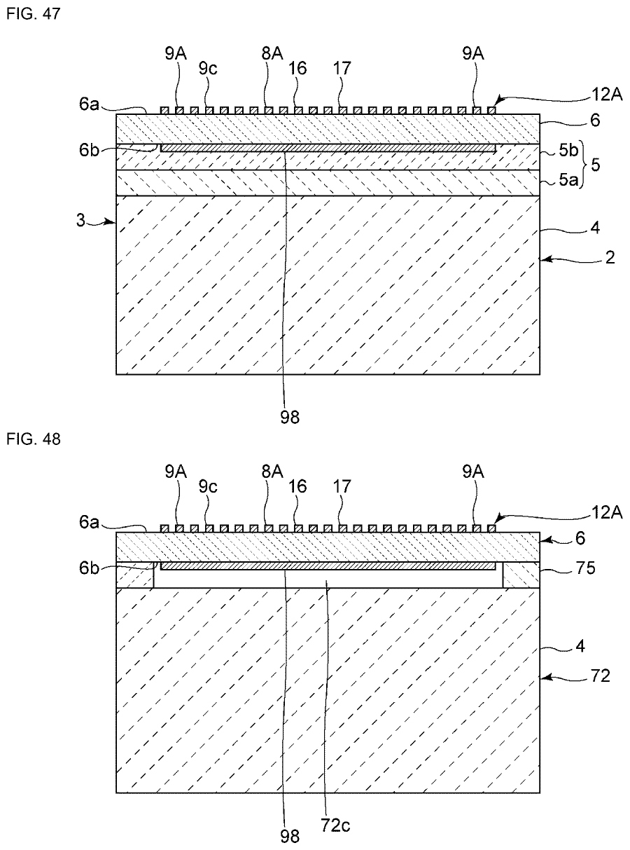

In the second modification illustrated in FIG. 47, a plate-shaped electrode 98 is provided on the second main surface 6b of the piezoelectric layer 6. The first resonator electrode 12A and the electrode 98 face each other across the piezoelectric layer 6. Another plate-shaped electrode 98 is also provided on the second main surface 6b so as to face the second resonator electrode 12B. The electrodes 98 are embedded within the second layer 5b.

In the third modification illustrated in FIG. 48, the piezoelectric substrate 72 is configured in the same or substantially the same manner as that of the first modification, and the same electrodes 98 as those of the second modification are provided on the second main surface 6b of the piezoelectric layer 6. The electrodes 98 are positioned within the hollow portion 72c.

The eighteenth to twentieth example embodiments and the modifications thereof illustrate examples in which the first and second resonator electrodes have the same or substantially the same configurations and arrangements as those of the first example embodiment. However, the piezoelectric substrates in the eighteenth to twentieth example embodiments and the modifications thereof can also be used in cases where the configurations and arrangements of the plurality of resonator electrodes are the same or substantially the same as those of example embodiments of the present invention, excluding the first example embodiment.

Acoustic wave devices according to example embodiments of the present invention can be, for example, a filter device. An example thereof is described below.

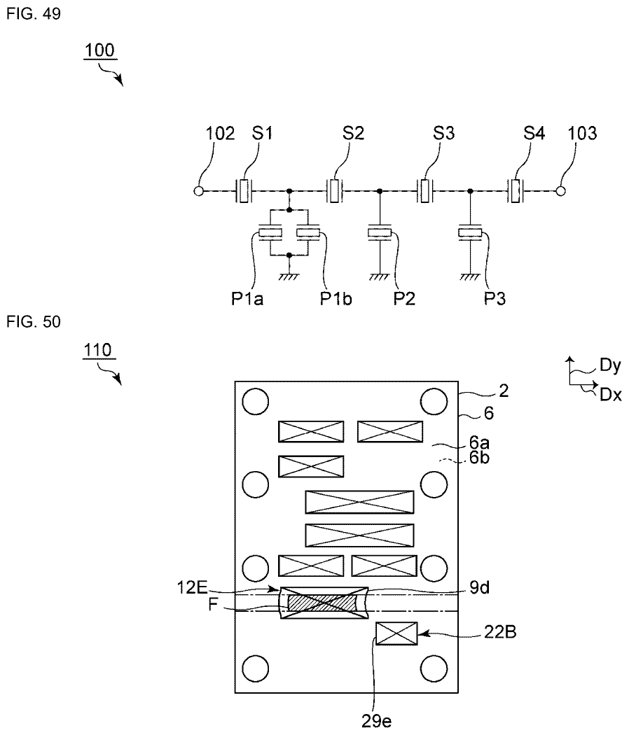

FIG. 49 is a circuit diagram of an acoustic wave device according to a twenty-first example embodiment of the present invention.

An acoustic wave device 100 of the twenty-first example embodiment is a ladder filter, for example. The acoustic wave device 100 includes a first signal terminal 102, a second signal terminal 103, a plurality of series arm resonators, and a plurality of parallel arm resonators. In the acoustic wave device 100, all of the series arm resonators and all of the parallel arm resonators are acoustic wave resonators. A plurality of resonator electrodes are provided on the piezoelectric substrate to define a plurality of acoustic wave resonators.

The first signal terminal 102 is an antenna terminal, for example. The antenna terminal is coupled to an antenna. However, the first signal terminal 102 does not need to define an antenna terminal. The first signal terminal 102 and the second signal terminal 103 may be configured as electrode pads or wiring, for example.

Specifically, the plurality of series arm resonators of the twenty-first example embodiment include a series arm resonator S1, a series arm resonator S2, a series arm resonator S3, and a series arm resonator S4. The plurality of series arm resonators are coupled in series between the first signal terminal 102 and the second signal terminal 103. The plurality of parallel arm resonators specifically include a parallel arm resonator P1a, a parallel arm resonator P1b, a parallel arm resonator P2, and a parallel arm resonator P3.

The parallel arm resonator P1a and the parallel arm resonator P1b are coupled to each other in parallel between the ground potential and the connecting point of the series arm resonators S1 and S2. The parallel arm resonator P2 is coupled between the ground potential and the connecting point of the series arm resonators S2 and S3. The parallel arm resonator P3 is coupled between the ground potential and the connecting point of the series arm resonators S3 and S4. The circuit configuration of the acoustic wave device 100 is not limited to that described above. The acoustic wave device 100 may include a longitudinally coupled resonator-type acoustic wave filter, for example.

In the twenty-first example embodiment, the parallel arm resonator P1a is the first acoustic wave resonator according to an example embodiment of the present invention. The parallel arm resonator P1b is the second acoustic wave resonator according to an example embodiment of the present invention. It is therefore possible to reduce or prevent the acoustic coupling between the parallel arm resonators P1a and P1b in the acoustic wave device 100 and thus reduce the degradation of the electrical characteristics. As a result, the degradation of the filter characteristics in the acoustic wave device 100 can be reduced.

In a configuration in the related art, acoustic wave resonators adjacent to each other tend to be acoustically coupled. In the twenty-first example embodiment, the first and second acoustic wave resonators are divided resonators connected in parallel. In this case, the first resonator electrode of the first acoustic wave resonator and the second resonator electrode of the second acoustic wave resonator tend to be arranged adjacent to each other. Even in the case where the first resonator electrode and the second resonator electrode are arranged adjacent to each other, the twenty-first example embodiment enables reduction or prevention of the acoustic coupling between the first and second acoustic wave resonators. Thus, it is possible to reduce or prevent the acoustic coupling between the acoustic wave resonators and suitably increase the layout flexibility. It is also possible to suitably increase the design flexibility of the acoustic wave device 100 as the filter device.

The arrangement of the first and second acoustic wave resonators on the circuit is not limited to that described above. For example, the first and second resonator electrodes may be adjacent to each other, and at least one of the first resonator electrode and the second resonator electrode may be the resonator electrode of any parallel arm resonator. Specifically, for example, the first resonator electrode may be the resonator electrode of the parallel arm resonator P2, while the second resonator electrode may be the resonator electrode of the series arm resonator S3 or the parallel arm resonator P3. In this case as well, the acoustic coupling between the first and second acoustic wave resonators can be reduced or prevented, and the layout flexibility can be improved.

Alternatively, the first and second resonator electrodes may be adjacent to each other, and at least one of the first resonator electrode and the second resonator electrode may be the resonator electrode of any series arm resonator. For example, the first resonator electrode may be the resonator electrode of the series arm resonator S2, while the second resonator electrode may be the resonator electrode of the parallel arm resonator P1a or the series arm resonator S3. In this case as well, the acoustic coupling between the first and second acoustic wave resonators can be reduced or prevented, and the layout flexibility can be improved.

In the twenty-first example embodiment, the first and second acoustic wave resonators are divided resonators connected in parallel and define and function as the parallel arm resonators. However, the first and second acoustic wave resonators may be divided resonators connected in series and define and function as the parallel arm resonators. Alternatively, the first and second acoustic wave resonators may be divided resonators connected in parallel or in series and define and function as the series arm resonators.

FIG. 50 is a simplified plan view of an acoustic wave device according to a twenty-second example embodiment of the present invention. In FIG. 50, wiring lines are omitted. In FIG. 50, the intersecting region of the first resonator electrode is indicated by hatching.

An acoustic wave device 110 is a filter device. The acoustic wave device 110 includes a plurality of acoustic wave resonators. The plurality of acoustic wave resonators include the first and second acoustic wave resonators.

The plurality of resonator electrodes are provided on the piezoelectric substrate 2 to define a plurality of acoustic wave resonators. The plurality of resonator electrodes include a first resonator electrode 12E and a second resonator electrode 22B. The first resonator electrode 12E is the resonator electrode of the first acoustic wave resonator. The first resonator electrode 12E is the curved resonator electrode. In the twenty-second example embodiment, the first resonator electrode 12E is configured in the same or substantially the same manner as the second modification of the first example embodiment. The outer sides of the plurality of electrode fingers correspond to the left in FIG. 50.

On the other hand, the second resonator electrode 22B is the resonator electrode of the second acoustic wave resonator. The second resonator electrode 22B is the linear resonator electrode. The second resonator electrode 22B is configured in the same or substantially the same manner as the second resonator electrode 22B of the second example embodiment. The plurality of resonator electrodes include at least one curved resonator electrode.

The first resonator electrode 12E and the second resonator electrode 22B are adjacent to each other. The intersecting region F of the first resonator electrode 12E and the intersecting region of the second resonator electrode 22B do not overlap each other when viewed in the first direction Dx, in which the propagation axis extends. In FIG. 50, the dotted-dashed line indicates the region that overlaps the intersecting region F of the first resonator electrode 12E when viewed in the first direction Dx. Such a configuration can reduce the influence of acoustic waves leaking from the first acoustic wave resonator on the second acoustic wave resonator. It is therefore possible to reduce or prevent the acoustic coupling between the first and second acoustic wave resonators and thus reduce the degradation of the electrical characteristics. As a result, it is possible to reduce the degradation of the filter characteristics of the acoustic wave device 110.

As illustrated in FIG. 50, two or more resonator electrodes are adjacent to the first resonator electrode 12E. However, among these resonator electrodes, it is preferable that the second resonator electrode 22B has the shortest distance from the first resonator electrode 12E. In this case, the configuration in which the intersecting region F of the first resonator electrode 12E does not overlap the intersecting region of the second resonator electrode 22B when viewed in the first direction Dx is preferable.

In the twenty-second example embodiment, the first resonator electrode 12E includes the first proximal electrode finger 9d. The second resonator electrode 22B includes the second proximal electrode finger 29e. As for the positional relationship in the first direction Dx, the second proximal electrode finger 29e is positioned on the inner side of a portion of the first proximal electrode finger 9d of the first resonator electrode 12E that has the shortest distance from the second proximal electrode finger 29e. More specifically, the second proximal electrode finger 29e is positioned on the inner side of the first proximal electrode finger 9d when viewed in the second direction Dy. However, the second proximal electrode finger 29e may be positioned on the outer side of a portion of the first proximal electrode finger 9d of the first resonator electrode 12E that has the shortest distance from the second proximal electrode finger 29e.

The second resonator electrode 22B may be the curved resonator electrode. In this case, as for the positional relationship in the first direction Dx, the first proximal electrode finger 9d may be positioned on the inner side of a portion of the second proximal electrode finger 29e of the second resonator electrode 22B that has the shortest distance from the first proximal electrode finger 9d. Alternatively, the first proximal electrode finger 9d may be positioned on the outer side of a portion of the second proximal electrode finger 29e of the second resonator electrode 22B that has the shortest distance from the first proximal electrode finger 9d. In the configuration of the twenty-second example embodiment, the second proximal electrode finger 29e may overlap the busbar of the first IDT electrode of the first resonator electrode 12E when viewed in the second direction Dy.

As described above, in the case where two or more resonator electrodes are adjacent to the first resonator electrode 12E, it is preferable that the intersecting region F of the first resonator electrode 12E does not overlap the intersecting regions of all of the resonator electrodes adjacent to the first resonator electrode 12E when viewed in the first direction Dx. This ensures more reliable reduction or prevention of the acoustic coupling between the acoustic wave resonators.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric substrate including a piezoelectric layer; and
a plurality of resonator electrodes on the piezoelectric substrate and each including a plurality of electrode fingers; wherein
each of the plurality of resonator electrodes includes an interdigital transducer (IDT) electrode;
the plurality of resonator electrodes include a first resonator electrode and a second resonator electrode;
at least one of the first resonator electrode and the second resonator electrode includes a curved resonator electrode in which each of the plurality of electrode fingers has a curved shape in plan view;
the first resonator electrode and the second resonator electrode face each other; and
one of the plurality of resonator electrodes is positioned on a convex side, in a direction in which the plurality of electrode fingers are arranged, of a portion including the curved shape of the curved resonator electrode.

2. An acoustic wave device, comprising:
a piezoelectric substrate including a piezoelectric layer; and
a plurality of resonator electrodes on the piezoelectric substrate and each including a plurality of electrode fingers; wherein
the piezoelectric layer includes a propagation axis;
each of the plurality of resonator electrodes includes an interdigital transducer (IDT) electrode;
the plurality of electrode fingers of the IDT electrode include a plurality of first electrode fingers and a plurality of second electrode fingers interdigitated with each other;
a distance between a first envelope and a second envelope denotes an intersecting width where the first envelope is a virtual line connecting tips of the plurality of second electrode fingers and the second envelope is a virtual line connecting tips of the plurality of first electrode fingers;
the plurality of resonator electrodes include a first resonator electrode and a second resonator electrode;
at least the first resonator electrode includes a curved resonator electrode in which each of the plurality of electrode fingers has a curved shape in plan view;
the first resonator electrode and the second resonator electrode face each other;
the second resonator electrode is positioned on a concave side in a direction in which the plurality of electrode fingers are arranged, of a portion including the curved shape of the curved resonator electrode finger in the first resonator electrode;
where the propagation axis extends in a first direction, a first distance denotes a shortest distance in the first direction between the first resonator electrode and the second resonator electrode;
where a second direction is a direction perpendicular or substantially perpendicular to the first direction, a second distance denotes a distance in the second direction between a center portion in the second direction of an electrode finger of the first resonator electrode positioned closest to the second resonator electrode and a center portion in the second direction of an electrode finger of the second resonator electrode positioned closest to the first resonator electrode;
a proximal intersecting width denotes a shorter one of the intersecting width at a portion of the IDT electrode of the first resonator electrode positioned closest to the second resonator electrode and the intersecting width at a portion of the IDT electrode of the second resonator electrode positioned closest to the first resonator electrode; and
the acoustic wave device includes at least one of:
a configuration in which the first distance is at least about 32λ where λ is a wavelength determined by an electrode finger pitch of the first resonator electrode; and
a configuration in which (Ly/La)×100 [%]≥about 12.4 [%] where Ly is the second distance and La is the proximal intersecting width.

3. An acoustic wave device, comprising:
a piezoelectric substrate including a piezoelectric layer; and
a plurality of resonator electrodes on the piezoelectric substrate and each including a plurality of electrode fingers; wherein
the piezoelectric layer includes a propagation axis;
each of the plurality of resonator electrodes includes an interdigital transducer (IDT) electrode and a pair of reflectors facing each other across the IDT electrode;
the IDT electrode and the pair of reflectors each include the plurality of electrode fingers;
the plurality of resonator electrodes include a first resonator electrode and a second resonator electrode;
at least the first resonator electrode includes a curved resonator electrode in which each of the plurality of electrode fingers has a curved shape in plan view;
a first proximal electrode finger denotes one of the plurality of electrode fingers of the first resonator electrode positioned closest to the second resonator electrode;
a second proximal electrode finger denotes one of the plurality of electrode fingers of the second resonator electrode positioned closest to the first resonator electrode; and
of the pair of reflectors of the first resonator electrode, a number of the plurality of electrode fingers of one of the pair of reflectors positioned closer to the IDT electrode of the second resonator electrode is greater than a number of the plurality of electrode fingers of another of the pair of reflectors.

4. An acoustic wave device, comprising:
a piezoelectric substrate including a piezoelectric layer; and
a plurality of resonator electrodes on the piezoelectric substrate and each including a plurality of electrode fingers; wherein
each of the plurality of resonator electrodes includes an IDT electrode;
the plurality of resonator electrodes include a first resonator electrode and a second resonator electrode, and
of the first resonator electrode and the second resonator electrode, at least the first resonator electrode is a curved resonator electrode in which each of the plurality of electrode fingers has a curved shape in plan view, the acoustic wave device further comprising:
an acoustic scattering pattern between the first resonator electrode and the second resonator electrode on the piezoelectric substrate.

5. An acoustic wave device, comprising:
a piezoelectric substrate including a piezoelectric layer; and
a plurality of resonator electrodes on the piezoelectric substrate and each including a plurality of electrode fingers; wherein
the piezoelectric layer includes a propagation axis;
each of the plurality of resonator electrodes includes an interdigital transducer (IDT) electrode;
the plurality of electrode fingers of the IDT electrode include a plurality of first electrode fingers and a plurality of second electrode fingers interdigitated with each other;
an intersecting region denotes a region between a first envelope and a second envelope where the first envelope is a virtual line connecting tips of the plurality of second electrode fingers and the second envelope is a virtual line connecting tips of the plurality of first electrode fingers;
the plurality of resonator electrodes include a first resonator electrode and a second resonator electrode;
at least the first resonator electrode includes a curved resonator electrode in which each of the plurality of electrode fingers has a curved shape in plan view;
the first resonator electrode and the second resonator electrode are adjacent to each other; and
where the propagation axis extends in a first direction, an intersecting region of the first resonator electrode does not overlap an intersecting region of the second resonator electrode when viewed in the first direction.

6. The acoustic wave device according to claim 1, wherein each of the first resonator electrode and the second resonator electrode includes the curved resonator electrode.

7. The acoustic wave device according to claim 2, wherein (Ly/La)×100 [%]≥about 49.5 [%].

8. The acoustic wave device according to claim 3, wherein, of the pair of reflectors of the second resonator electrode, a number of the plurality of electrode fingers of one of the pair of reflectors positioned closer to the IDT electrode of the first resonator electrode is greater than a number of the plurality of electrode fingers of another of the pair of reflectors.

9. The acoustic wave device according to claim 5, wherein the second resonator electrode has a shortest distance from the first resonator electrode among the plurality of resonator electrodes.

10. The acoustic wave device according to claim 1, wherein
the piezoelectric layer includes a propagation axis;
a first proximal electrode finger denotes one of the plurality of electrode fingers of the first resonator electrode positioned closest to the second resonator electrode;
a second proximal electrode finger denotes one of the plurality of electrode fingers of the second resonator electrode positioned closest to the first resonator electrode; and
where the propagation axis extends in a first direction, the first proximal electrode finger and the second proximal electrode finger overlap each other when viewed in the first direction.

11. The acoustic wave device according to claim 1, wherein
each of the plurality of resonator electrodes includes a pair of reflectors facing each other across the IDT electrode; and
the IDT electrode and the pair of reflectors each include the plurality of electrode fingers.

12. The acoustic wave device according to claim 2, wherein
the plurality of resonator electrodes include a plurality of curved resonator electrodes each having the curved shape in plan view; and
the second resonator electrode is the curved resonator electrode.

13. The acoustic wave device according to claim 12, wherein
a convex side, in the direction in which the plurality of electrode fingers are arranged, of a portion including the curved shape of the electrode finger in the curved resonator electrode corresponds to an outer side of the portion including the curved shape, and a concave side in the direction in which the plurality of electrode fingers are arranged corresponds to an inner side;
a first proximal electrode finger denotes one of the plurality of electrode fingers of the first resonator electrode positioned closest to the second resonator electrode;
a second proximal electrode finger denotes one of the plurality of electrode fingers of the second resonator electrode positioned closest to the first resonator electrode;
the second proximal electrode finger is positioned on the inner side of a portion of the first proximal electrode finger with a shortest distance from the second proximal electrode finger; and
the first proximal electrode finger is positioned on either the outer side or the inner side of a portion of the second proximal electrode finger with a shortest distance from the first proximal electrode finger.

14. The acoustic wave device according to claim 1, wherein
the piezoelectric substrate includes a support substrate; and
the piezoelectric layer is on the support substrate.

15. The acoustic wave device according to claim 14, wherein the piezoelectric substrate includes an intermediate layer between the support substrate and the piezoelectric layer.

16. The acoustic wave device according to claim 14, wherein
a hollow portion is provided in the piezoelectric substrate; and
a portion of the support substrate and a portion of the piezoelectric layer face each other across the hollow portion.

17. The acoustic wave device according to claim 1, wherein the piezoelectric substrate includes only the piezoelectric layer.

18. The acoustic wave device according to claim 1, wherein
the first resonator electrode and the second resonator electrode are adjacent to each other; and
at least one of the first resonator electrode and the second resonator electrode defines a resonator electrode of a parallel arm resonator.

19. The acoustic wave device according to claim 1, wherein
the first resonator electrode and the second resonator electrode are adjacent to each other; and
at least one of the first resonator electrode and the second resonator electrode defines a resonator electrode of a series arm resonator.

20. The acoustic wave device according to claim 1, wherein each of the first resonator electrode and the second resonator electrode defines a resonator electrode of a divided resonator.
